(19) United States
(12) Patent Application Publication
(10) Pub. No.: US 2024/0047335 A1
(43) Pub. Date: Feb. 8, 2024

(54) PACKAGE COMPRISING AN INTEGRATED DEVICE AND A FIRST METALLIZATION PORTION COUPLED TO A SECOND METALLIZATION PORTION

(71) Applicant: QUALCOMM Incorporated, San Diego, CA (US)

(72) Inventors: Hong Bok WE, San Diego, CA (US); Joan Rey Villarba BUOT, Escondido, CA (US); Aniket PATIL, San Diego, CA (US)

(21) Appl. No.: 17/879,594

(22) Filed: Aug. 2, 2022

(51) Int. Cl. H01L 23/498; H01L 25/16; H01L 21/48; H01L 21/56

(52) U.S. Cl. CPC H01L 23/49838; H01L 25/16; H01L 21/4853; H01L 21/486; H01L 21/565; H01L 23/49816; H01L 23/49833; H01L 2224/16227; H01L 2224/16238; H01L 2224/16237; H01L 2224/32225; H01L 24/32

(57) ABSTRACT

A package comprising a first integrated device, a first metallization portion coupled to the first integrated device, a second integrated device, a second metallization portion coupled to the second integrated device and the first metallization portion, and an encapsulation layer coupled to the first metallization portion, the second integrated device and the second metallization portion. The first metallization portion includes at least one first dielectric layer and a first plurality of metallization interconnects. The second metallization portion includes at least one second dielectric layer and a second plurality of metallization interconnects.

### FIELD

Various features relate to packages with a metallization portion and an integrated device.

### BACKGROUND

A package may include a substrate and integrated devices. These components are coupled together to provide a package that may perform various electrical functions. There is an ongoing need to provide better performing packages and reduce the overall size of the packages.

### SUMMARY

Various features relate to packages with a metallization portion and an integrated device.

One example provides a package comprising a first integrated device, a first metallization portion coupled to the first integrated device, a second integrated device, a second metallization portion coupled to the second integrated device and the first metallization portion, and an encapsulation layer coupled to the first metallization portion, the second integrated device and the second metallization portion. The first metallization portion includes at least one first dielectric layer and a first plurality of metallization interconnects. The second metallization portion includes at least one second dielectric layer and a second plurality of metallization interconnects.

Another example provides a device comprising a first package, a second integrated device, a second metallization portion, and an encapsulation layer coupled to the first package, the second integrated device and the second metallization portion. The first package comprises a first integrated device and a first metallization portion coupled to the first integrated device. The second metallization portion is coupled to the second integrated device and the first metallization portion of the first package. The first metallization portion comprises at least one first dielectric layer and a first plurality of metallization interconnects. The second metallization portion comprises at least one second dielectric layer and a second plurality of metallization interconnects.

Another example provides a method for fabricating a package. The method provides a first package comprising a first integrated device and a first metallization portion coupled to the first integrated device. The first metallization portion comprises at least one first dielectric layer and a first plurality of metallization interconnects. The method provides a second integrated device. The method forms an encapsulation layer over the first package and the second integrated device. The method forms a second metallization portion over the second integrated device, the first metallization portion of the first package and the encapsulation layer. The second metallization portion comprises at least one second dielectric layer and a second plurality of metallization interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a first metallization portion and a second metallization portion.

FIG. 2 illustrates an exemplary cross sectional profile view of a package that includes a first metallization portion and a second metallization portion.

FIG. 3 illustrates an exemplary cross sectional profile view of a package that includes a first metallization portion and a second metallization portion.

FIG. 4A-4F illustrate an exemplary sequence for fabricating a package that includes a first metallization portion and a second metallization portion.

FIG. 5A-5F illustrate an exemplary sequence for fabricating a package that includes a first metallization portion and a second metallization portion.

FIG. 6 illustrates an exemplary flow chart of a method for fabricating a package that includes a first metallization portion and a second metallization portion.

FIGS. 7A-7B illustrate an exemplary sequence for fabricating a metallization portion.

FIG. 8 illustrates an exemplary flow chart of a method for fabricating a metallization portion.

FIG. 9 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package that includes a first integrated device, a first metallization portion coupled to the first integrated device, a second integrated device, a second metallization portion coupled to the second integrated device and the first metallization portion, and an encapsulation layer coupled to the first metallization portion, the second integrated device and the second metallization portion. The first metallization portion comprises at least one first dielectric layer and a first plurality of metallization interconnects. The second metallization portion comprises at least one second dielectric layer and a second plurality of metallization interconnects.

### Exemplary Packages Comprising a First Metallization Portion and a Second Metallization Portion

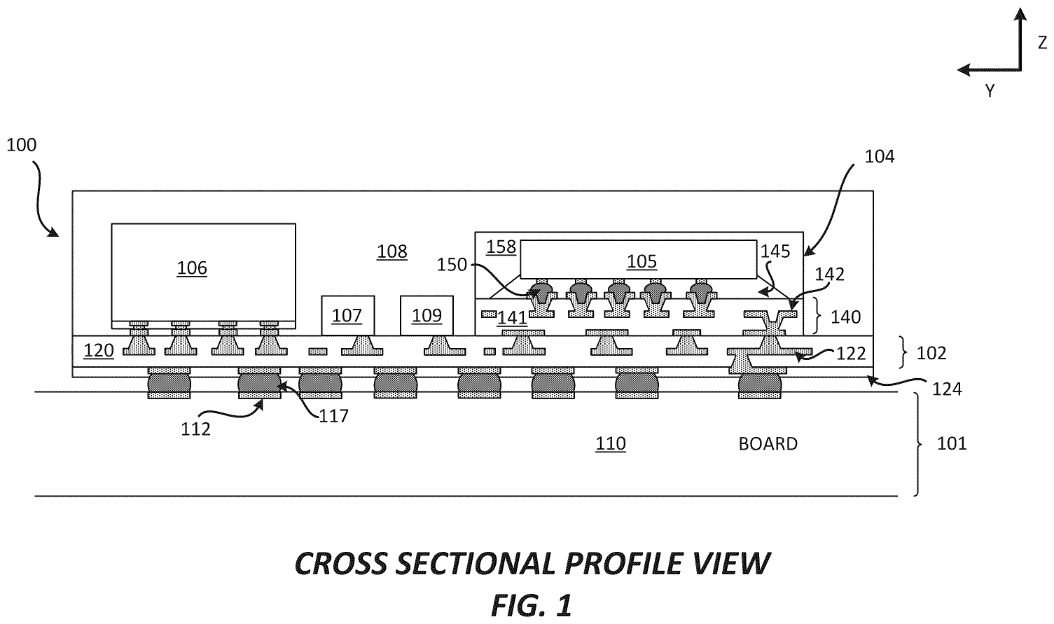

FIG. 1 illustrates a cross sectional profile view of a package 100 that includes a first metallization portion and a second metallization portion. The package 100 is coupled to a board 101 through a plurality of solder interconnects 117. The board 101 includes at least one board dielectric layer 110 and a plurality of board interconnects 112. The board 101 may include a printed circuit board (PCB). The package 100 is coupled to the plurality of board interconnects 112 of the board 101 through the plurality of solder interconnects 117.

The package 100 includes a metallization portion 102, an integrated device 104, an integrated device 106, a passive device 107, a passive device 109, an encapsulation layer 108, and a solder resist layer 124. The integrated device 104 is coupled to the metallization portion 102. The integrated device 106 is coupled to the metallization portion 102. The passive device 107 and the passive device 109 are each coupled to the metallization portion 102. The encapsulation layer 108 is coupled to the metallization portion 102. For example, the encapsulation layer 108 is coupled to a surface of the metallization portion 102. The encapsulation layer 108 is coupled to the integrated device 104, the integrated device 106, the passive device 107 and the passive device 109. The encapsulation layer 108 encapsulates the integrated device 104, the integrated device 106, the passive device 107 and the passive device 109.

The metallization portion 102 includes at least one dielectric layer 120 and a plurality of metallization interconnects 122. The metallization portion 102 may include a redistribution portion (e.g., first redistribution portion). The metallization portion 102 may include a first side and a second side. The first side may be a top side, and the second side may be a bottom side. The plurality of metallization interconnects 122 may include a plurality of redistribution interconnects (e.g., first plurality of redistribution interconnects). The metallization portion 102 may be a front side metallization portion (e.g., front side redistribution portion) of the package 100. The metallization portion 102 may be a means for metallization interconnection (e.g., means for front side metallization interconnection). The solder resist layer 124 is coupled to a surface of the metallization portion 102.

The integrated device 106 is coupled to the metallization portion 102. For example, the integrated device 106 is coupled to the plurality of metallization interconnects 122 of the metallization portion 102. At least some of the metallization interconnects from the plurality of metallization interconnects 122 may be coupled to (e.g., touching) interconnects of the integrated device 106.

The integrated device 104 includes a metallization portion 140, an integrated device 105, an encapsulation layer 158, an underfill 145, and a plurality of solder interconnects 150. The integrated device 105 may include a bare die (e.g., semiconductor bare die). The integrated device 105 may include a chip. The integrated device 104 may be an integrated device package (e.g., first package, first integrated device package). The integrated device 105 is coupled to the metallization portion 140 through the plurality of solder interconnects 150. The underfill 145 may be located between the integrated device 105 and the metallization portion 140. The metallization portion 140 includes at least one dielectric layer 141 and a plurality of metallization interconnects 142. The integrated device 105 is coupled to the plurality of metallization interconnects 142 of the metallization portion 140 through the plurality of solder interconnects 150. The encapsulation layer 158 is coupled to the integrated device 105 and the metallization portion 140. The encapsulation layer 158 encapsulates at least the integrated device 105 and the underfill 145. The encapsulation layer 158 may be coupled to the encapsulation layer 108. For example, an outer surface of the encapsulation layer 158 may be touching an inner surface of the encapsulation layer 108. The encapsulation layer 108 and/or the encapsulation layer 158 may include a mold, a resin and/or an epoxy. The encapsulation layer 108 and/or the encapsulation layer 158 may be a means for encapsulation. The encapsulation layer 108 and/or the encapsulation layer 158 may be provided by using a compression and transfer molding process, a sheet molding process, or a liquid molding process. The encapsulation layer 108 and the encapsulation layer 158 may include the same and/or similar encapsulation material. In some implementations, the encapsulation layer 108 and the encapsulation layer 158 may include different encapsulation material. In some implementations, there may be an interface between the encapsulation layer 108 and the encapsulation layer 158.

As mentioned above, the integrated device 104 is coupled to the metallization portion 102. As shown in FIG. 1, the metallization portion 140 is coupled to the metallization portion 102. The plurality of metallization interconnects 142 of the metallization portion 140 is coupled to the plurality of metallization interconnects 122 of the metallization portion 102. The metallization portion 140 may be a first metallization portion. The metallization portion 102 may be a second metallization portion.

The metallization portion 140 may include a redistribution portion (e.g., second redistribution portion). The metallization portion 140 may include a first side and a second side. The first side may be a top side, and the second side may be a bottom side. The plurality of metallization interconnects 142 may include a plurality of redistribution interconnects (e.g., second plurality of redistribution interconnects). The metallization portion 140 may be a means for metallization interconnection (e.g., a means for first metallization interconnection). The plurality of metallization interconnects 142 may include a first plurality of metallization interconnects. The at least one dielectric layer 141 may include at least one first dielectric layer. The integrated device 105 is coupled to the top side of the metallization portion 140. The top side of the metallization portion 140 faces the integrated device 105. However, in some implementations, the integrated device 105 may be coupled to the bottom side of the metallization portion 140. In such an instance, the top side of the metallization portion 140 may be coupled to the metallization portion 102.

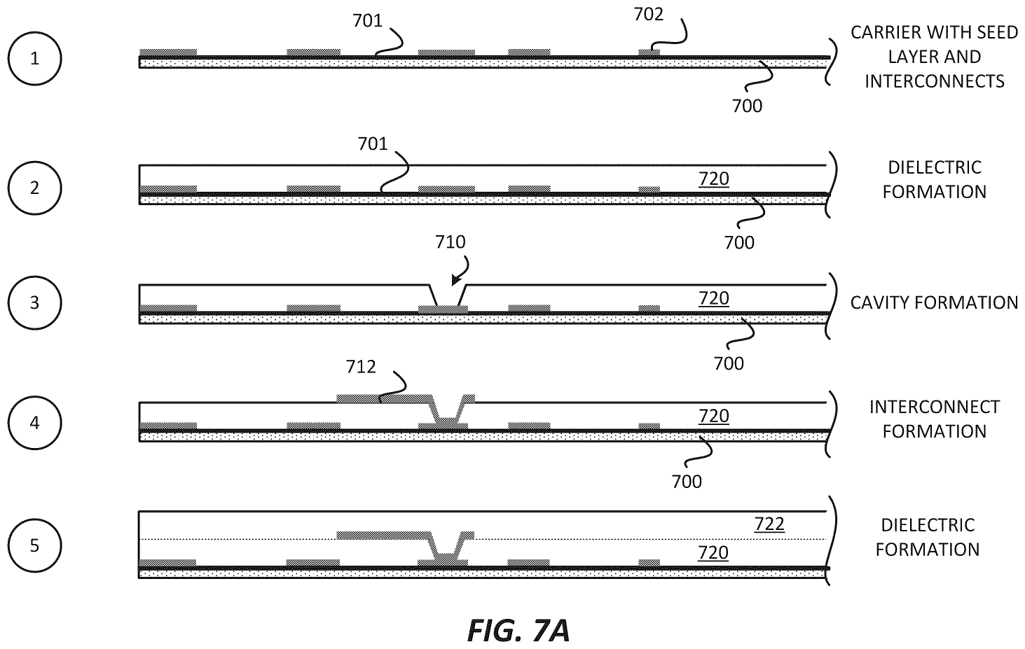

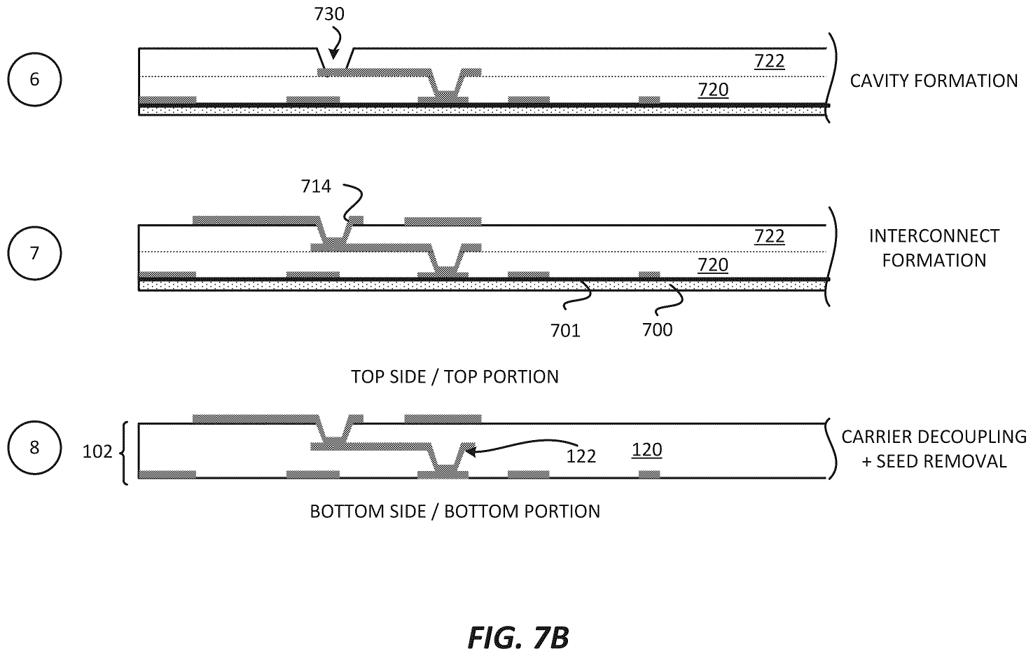

The metallization portion 102 may include a redistribution portion (e.g., second redistribution portion). The metallization portion 102 may include a first side and a second side. The first side may be a top side, and the second side may be a bottom side. The plurality of metallization interconnects 122 may include a plurality of redistribution interconnects (e.g., second plurality of redistribution interconnects). The metallization portion 102 may be a means for metallization interconnection (e.g., a means for second metallization interconnection). The plurality of metallization interconnects 122 may include a second plurality of metallization interconnects. The at least one dielectric layer 120 may include at least one second dielectric layer. The bottom side of the metallization portion 140 is coupled to the bottom side of the metallization portion 102. The bottom side of the metallization portion 102 faces the integrated device 105. The concepts of a bottom side and/or a top side of a metallization portion is further described below in at least FIGS. 7A-7B.

As mentioned above, a metallization portion (e.g., 102, 140) may include a redistribution portion that includes redistribution interconnects (e.g., redistribution layer (RDL) interconnects). A redistribution interconnect may include portions that have a U-shape or V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). It is noted that the metallization portion 102 and the metallization portion 140 are shown with metallization interconnects that have different shapes. In some implementations, the plurality of metallization interconnects 142 of the metallization portion 140 may have cross sectional profile shapes that are like and/or similar to the plurality of metallization interconnects 122 of the metallization portion 102 shown in FIG. 1. In some implementations, the plurality of metallization interconnects 122 of the metallization portion 102 may have cross sectional profile shapes that are like and/or similar to the plurality of metallization interconnects 142 of the metallization portion 140 shown in FIG. 1.

The metallization portion 140 may be coupled to the metallization portion 102 such that the bottom side of the metallization portion 140 is coupled to the bottom side of the metallization portion 102. However, different implementations may couple the metallization portion 140 to the metallization portion 102 differently. For example, in some implementations, the metallization portion 140 may be coupled to the metallization portion 102 such that the top side of the metallization portion 140 is coupled to the bottom side of the metallization portion 102. Examples of what is meant as a bottom side and a top side of a metallization portion is described and illustrated below in at least FIG. 7B.

As mentioned above, the metallization portion 140 may include a redistribution portion (e.g., first redistribution portion) and the metallization portion 102 may include a redistribution portion (e.g., second redistribution portion). In some implementations, a bottom portion/bottom side of the first redistribution portion is directly coupled to a bottom portion/bottom side of the second redistribution portion.

In some implementations, the metallization portion 140 and/or the metallization portion 102 may form and/or be defined as a continuous and/or contiguous metallization portion. For example, the at least one dielectric layer 141 and the at least one dielectric layer 120 may be considered part of the same dielectric layer. In some implementations, the at least one dielectric layer 141 and the at least one dielectric layer 120 may include the same dielectric material (e.g., polyimide (PI)). In some implementations, there may be an interface between the dielectric layer of the metallization portion 140 and the dielectric layer of the metallization portion 102. In some implementations, the metallization portion 140 and the metallization portion 102 may be considered as two separate metallization portions that are coupled to each other.

The metallization portion 140 may have a smaller footprint than the metallization portion 102. For example, the metallization portion 140 may have a width that is smaller than the width of the metallization portion 102. In some implementations, the metallization portion 140 may have a surface planar area that is smaller than a surface planar area of the metallization portion 102. In some implementations, the metallization portion 140 is coupled to the metallization portion 102 such that there is no solder interconnect between the metallization portion 140 and the metallization portion 102. Thus, at least some of the metallization interconnects of the metallization portion 140 may be in direct contact (e.g., touching) with at least some of the metallization interconnects of the metallization portion 102. This may help provide packages that are thinner and that have smaller form factors.

The integrated device 105 is configured to be electrically coupled to the integrated device 106 through at least one electrical path (e.g., for input/output signals) that includes (i) at least one solder interconnect from the plurality of solder interconnects 150, (ii) at least one metallization interconnect from the plurality of metallization interconnects 142 and (iii) at least one metallization interconnect from the plurality of metallization interconnects 122. Thus, the integrated device 105 is configured to be electrically coupled to the integrated device 106 through the metallization portion 140 and the metallization portion 102 such that at least one electrical path between the integrated device 105 and the integrated device 106 extends through the metallization portion 140 and the metallization portion 102.

An electrical path between the board 101 and the integrated device 105 may include (i) at least one board interconnect from the plurality of board interconnects 112, (ii) at least one solder interconnect from the plurality of solder interconnects 117, (iii) at least one metallization interconnect from the plurality of metallization interconnects 122, (iv) at least one metallization interconnect from the plurality of metallization interconnects 142, and (v) at least one solder interconnect from the plurality of solder interconnects 150.

The integrated device 105 is configured to be electrically coupled to the passive device 107 through at least one electrical path (e.g., for power) that includes (i) at least one solder interconnect from the plurality of solder interconnects 150, (ii) at least one metallization interconnect from the plurality of metallization interconnects 142 and (iii) at least one metallization interconnect from the plurality of metallization interconnects 122. Thus, the integrated device 105 is configured to be electrically coupled to the passive device 107 through the metallization portion 140 and the metallization portion 102.

Similarly, the integrated device 105 is configured to be electrically coupled to the passive device 109 through at least one electrical path (e.g., for power) that includes (i) at least one solder interconnect from the plurality of solder interconnects 150, (ii) at least one metallization interconnect from the plurality of metallization interconnects 142 and (iii) at least one metallization interconnect from the plurality of metallization interconnects 122. Thus, the integrated device 105 is configured to be electrically coupled to the passive device 109 through the metallization portion 140 and the metallization portion 102.

The passive device 107 and the passive device 109 may each include pads (not shown) that may be coupled to (e.g., touching) the metallization portion 102. For example, the passive device 107 and the passive device 109 may each include pads (not shown) that may be coupled to metallization interconnects of the metallization portion 102.

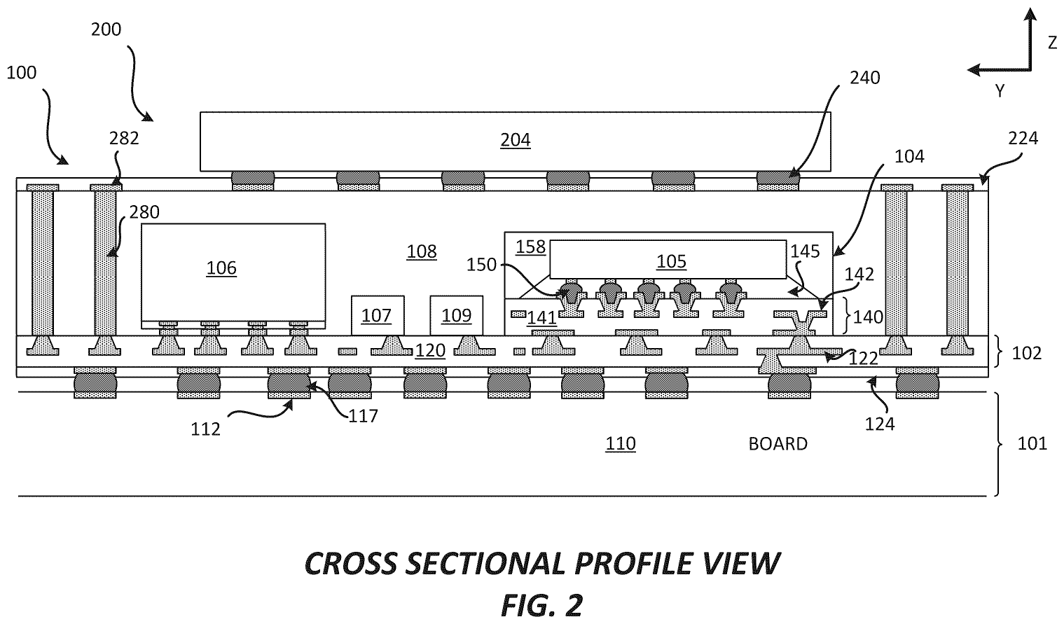

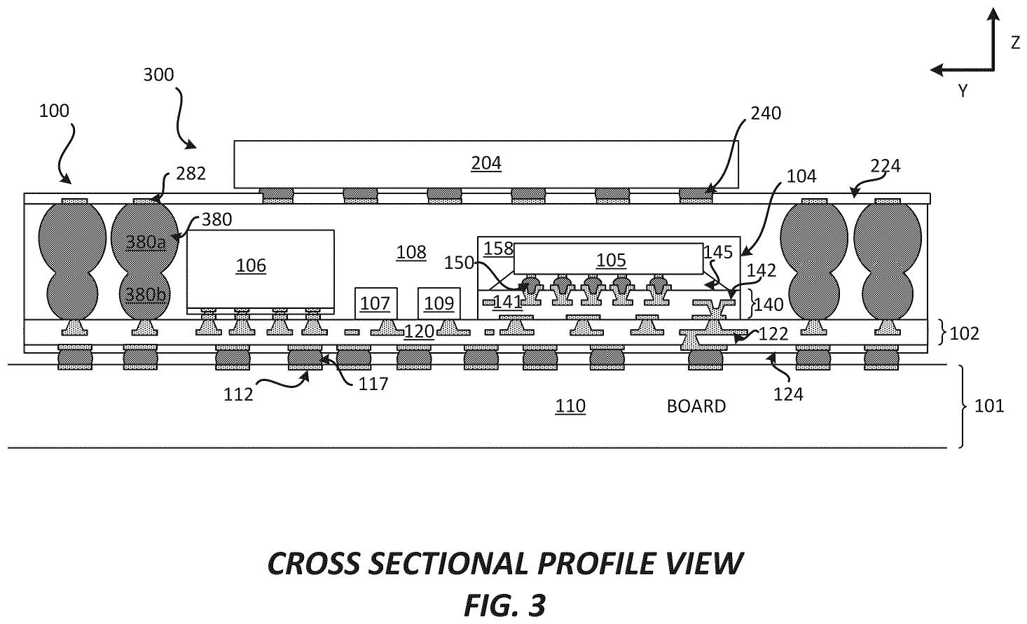

The package 100 of FIG. 1 illustrates an example of a package comprising at least two metallization portions (e.g., two redistribution portions) that help provide packages with an overall smaller thickness. FIGS. 2 and 3 illustrate other examples of packages comprising at least two metallization portions that help provide packages with an overall smaller thickness.

FIG. 2 illustrates a package 200 that includes a first metallization portion and a second metallization portion. The package 200 includes the package 100 and the integrated device 204. The integrated device 204 is coupled to the package 100 through a plurality of solder interconnects 240. The package 200 may include a package on package (PoP). The package 200 is coupled to the board 101 through a plurality of solder interconnects 117. The board 101 includes at least one board dielectric layer 110 and a plurality of board interconnects 112. The board 101 may include a printed circuit board (PCB). The package 200 is coupled to the plurality of board interconnects 112 of the board 101 through the plurality of solder interconnects 117.

The package 100 of FIG. 2 is similar to the package 100 of FIG. 1. The package 100 of FIG. 2 includes the same or similar components as the package 100 of FIG. 1. The package 100 includes the metallization portion 102, the integrated device 104, the integrated device 106, the passive device 107, the passive device 109, the encapsulation layer 108, a plurality of through mold vias (TMVs) 280, a plurality of interconnects 282, the solder resist layer 124 and a solder resist layer 224. The plurality of through mold vias 280 are coupled located in the encapsulation layer 108 and extend through the thickness (e.g., entire thickness) of the encapsulation layer 108. The plurality of through mold vias 280 are coupled to the metallization portion 102. The plurality of through mold vias 280 are coupled to the plurality of metallization interconnects 122. The plurality of interconnects 282 are coupled to a surface (e.g., top surface) of the encapsulation layer 108. The plurality of interconnects 282 are coupled to the plurality of through mold vias 280. The integrated device 204 is coupled to the plurality of interconnects 282 through the plurality of solder interconnects 240. The solder resist layer 224 is coupled to a surface (e.g., top surface) of the encapsulation layer 108. The plurality of through mold vias 280 are an example of a plurality of through mold interconnects.

The integrated device 105 is configured to be electrically coupled to the integrated device 204 through at least one electrical path (e.g., for input/output signals) that includes (i) at least one solder interconnect from the plurality of solder interconnects 150, (ii) at least one metallization interconnect from the plurality of metallization interconnects 142, (iii) at least one metallization interconnect from the plurality of metallization interconnects 122, (iv) at least one via from the plurality of through mold vias 280, (v) at least one interconnect from the plurality of interconnects 282, and (vi) at least one solder interconnect from the plurality of solder interconnects 240. Thus, the integrated device 105 is configured to be electrically coupled to the integrated device 204 through the metallization portion 140 and the metallization portion 102 such that at least one electrical path between the integrated device 105 and the integrated device 204 extends through at least the metallization portion 140 and the metallization portion 102.

The integrated device 106 is configured to be electrically coupled to the integrated device 204 through at least one electrical path (e.g., for input/output signals) that includes (i) at least one metallization interconnect from the plurality of metallization interconnects 122, (ii) at least one via from the plurality of through mold vias 280, (iii) at least one interconnect from the plurality of interconnects 282, and (iv) at least one solder interconnect from the plurality of solder interconnects 240. Thus, the integrated device 106 is configured to be electrically coupled to the integrated device 204 through the metallization portion 102 such that at least one electrical path between the integrated device 106 and the integrated device 204 extends through at least the metallization portion 102.

FIG. 3 illustrates a package 300 that includes a first metallization portion and a second metallization portion. The package 300 includes the package 100 and the integrated device 204. The integrated device 204 is coupled to the package 100 through a plurality of solder interconnects 240. The package 300 may include a package on package (PoP). The package 300 is coupled to the board 101 through a plurality of solder interconnects 117. The board 101 includes at least one board dielectric layer 110 and a plurality of board interconnects 112. The board 101 may include a printed circuit board (PCB). The package 300 is coupled to the plurality of board interconnects 112 of the board 101 through the plurality of solder interconnects 117.

The package 100 of FIG. 3 is similar to the package 100 of FIG. 1. The package 100 of FIG. 3 includes the same or similar components as the package 100 of FIG. 1. The package 100 includes the metallization portion 102, the integrated device 104, the integrated device 106, the passive device 107, the passive device 109, the encapsulation layer 108, a plurality of through mold solder interconnects 380, a plurality of interconnects 282, the solder resist layer 124 and a solder resist layer 224. The plurality of through mold solder interconnects 380 are located in the encapsulation layer 108 and extend through the thickness (e.g., entire thickness) of the encapsulation layer 108. The plurality of through mold solder interconnects 380 are coupled to the metallization portion 102. The plurality of through mold solder interconnects 380 are coupled to the plurality of metallization interconnects 122. The plurality of interconnects 282 are coupled to a surface (e.g., top surface) of the encapsulation layer 108. The plurality of interconnects 282 are coupled to the plurality of through mold solder interconnects 380. The integrated device 204 is coupled to the plurality of interconnects 282 through the plurality of solder interconnects 240. The solder resist layer 224 is coupled to a surface (e.g., top surface) of the encapsulation layer 108.

The plurality of through mold solder interconnects 380 may include a through mold solder interconnect 380a and a through mold solder interconnect 380b. The through mold solder interconnect 380a is coupled to the through mold solder interconnect 380b. The through mold solder interconnect 380a may have a diameter (e.g., first diameter) that is greater than a diameter (e.g., second diameter) of the through mold solder interconnect 380b. The through mold solder interconnect 380a may have a width (e.g., first width) that is greater than a width (e.g., second width) of the through mold solder interconnect 380b. The plurality of through mold solder interconnects 380 are an example of a plurality of through mold interconnects.

The integrated device 105 is configured to be electrically coupled to the integrated device 204 through at least one electrical path (e.g., for input/output signals) that includes (i) at least one solder interconnect from the plurality of solder interconnects 150, (ii) at least one metallization interconnect from the plurality of metallization interconnects 142, (iii) at least one metallization interconnect from the plurality of metallization interconnects 122, (iv) at least one solder interconnect from the plurality of through mold solder interconnects 380, (v) at least one interconnect from the plurality of interconnects 282, and (vi) at least one solder interconnect from the plurality of solder interconnects 240. Thus, the integrated device 105 is configured to be electrically coupled to the integrated device 204 through the metallization portion 140 and the metallization portion 102 such that at least one electrical path between the integrated device 105 and the integrated device 204 extends through at least the metallization portion 140 and the metallization portion 102.

The integrated device 106 is configured to be electrically coupled to the integrated device 204 through at least one electrical path (e.g., for input/output signals) that includes (i) at least one metallization interconnect from the plurality of metallization interconnects 122, (ii) at least one solder interconnect from the plurality of through mold solder interconnects 380, (iii) at least one interconnect from the plurality of interconnects 282, and (iv) at least one solder interconnect from the plurality of solder interconnects 240. Thus, the integrated device 106 is configured to be electrically coupled to the integrated device 204 through the metallization portion 102 such that at least one electrical path between the integrated device 106 and the integrated device 204 extends through at least the metallization portion 102.

An integrated device (e.g., 104, 105, 106, 204) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 104, 105, 106, 204) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

The package (e.g., 100, 200, 300) may be implemented in a radio frequency (RF) package. The RF package may be a radio frequency front end (RFFE) package. A package (e.g., 100, 200, 300) may be configured to provide Wireless Fidelity (WiFi) communication and/or cellular communication (e.g., 2G, 3G, 4G, 5G). The packages (e.g., 100, 200, 300) may be configured to support Global System for Mobile (GSM) Communications, Universal Mobile Telecommunications System (UMTS), and/or Long-Term Evolution (LTE). The packages (e.g., 100, 200, 300) may be configured to transmit and receive signals having different frequencies and/or communication protocols.

### Exemplary Sequence for Fabricating a Package Comprising a First Metallization Portion and a Second Metallization Portion

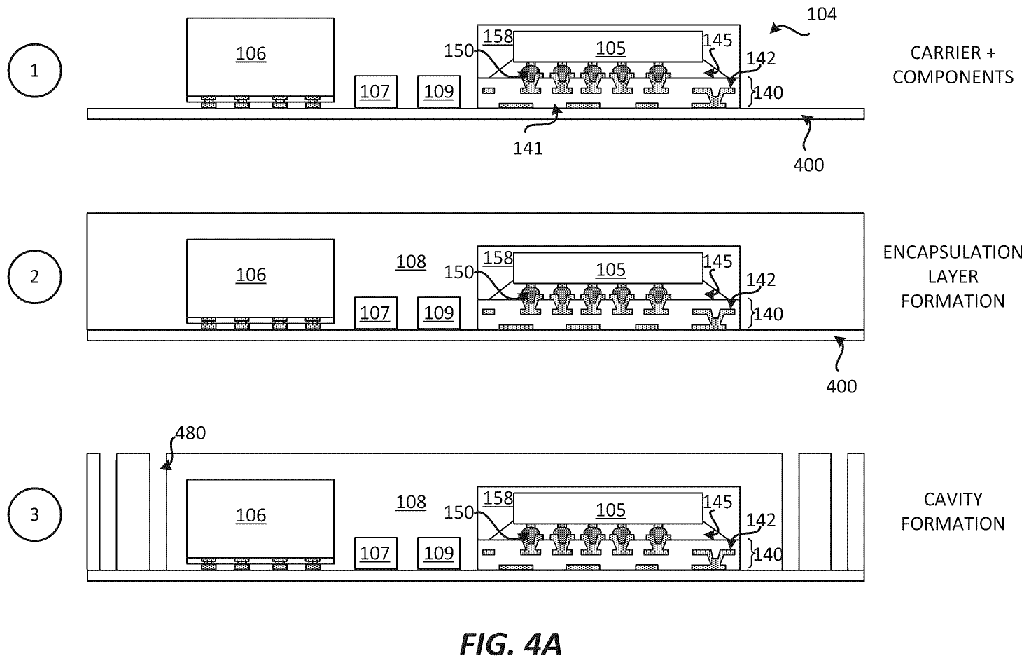

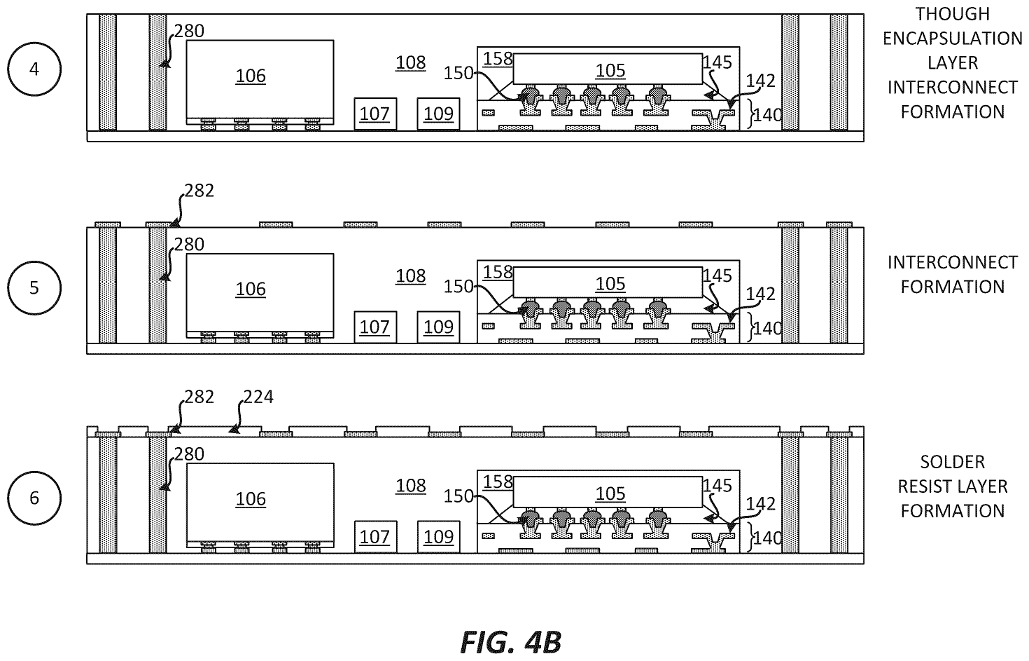

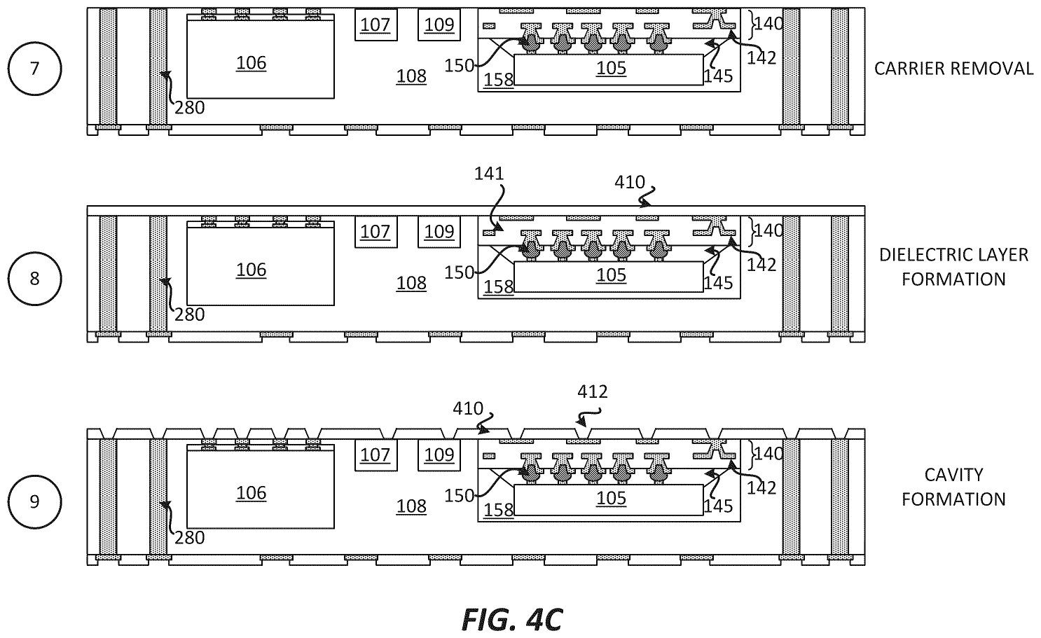

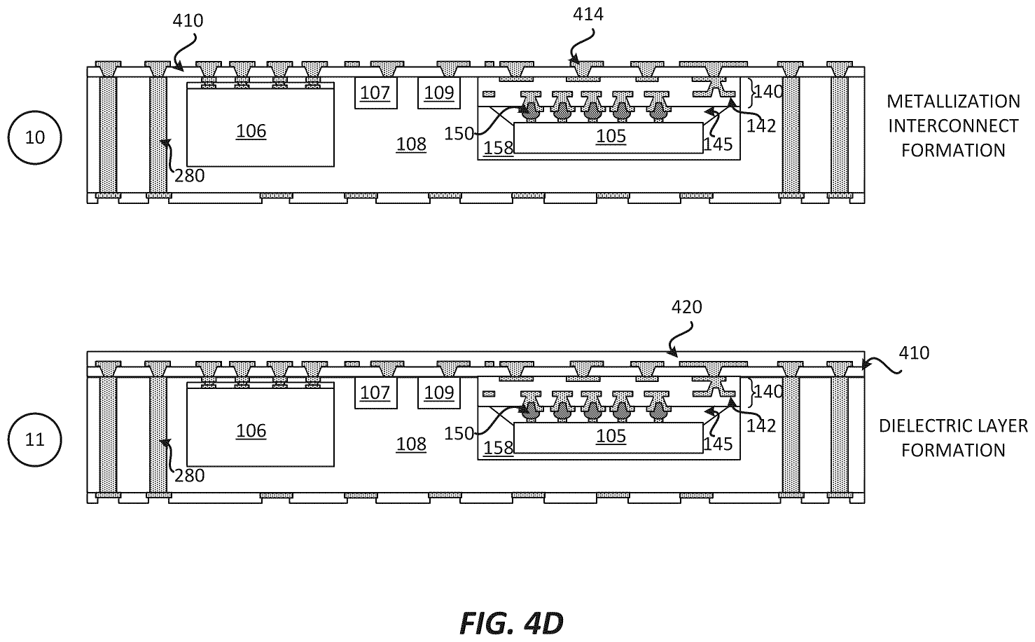

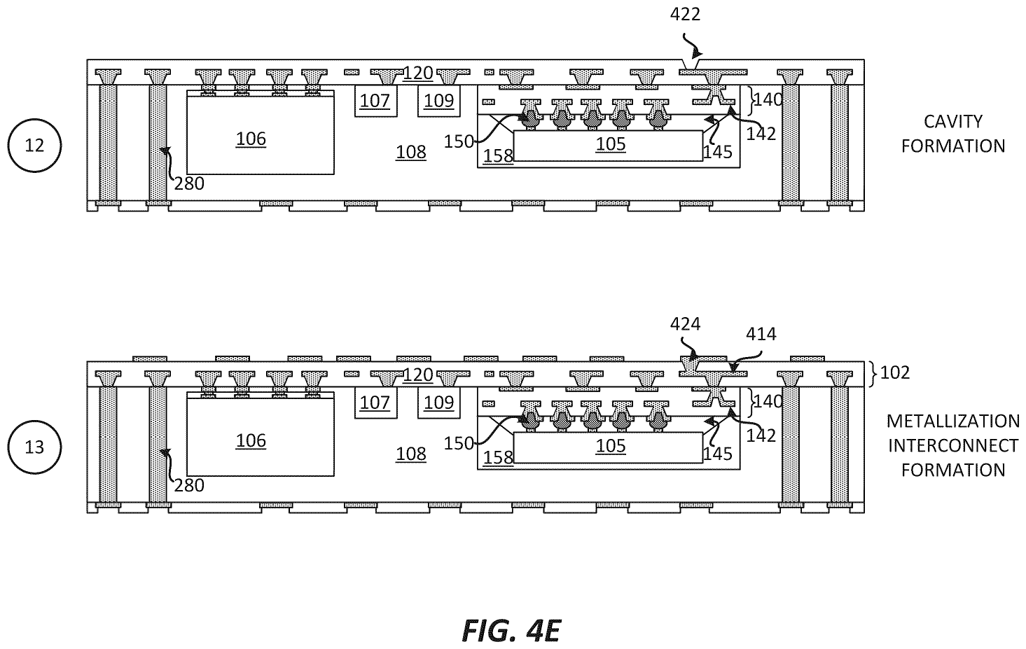

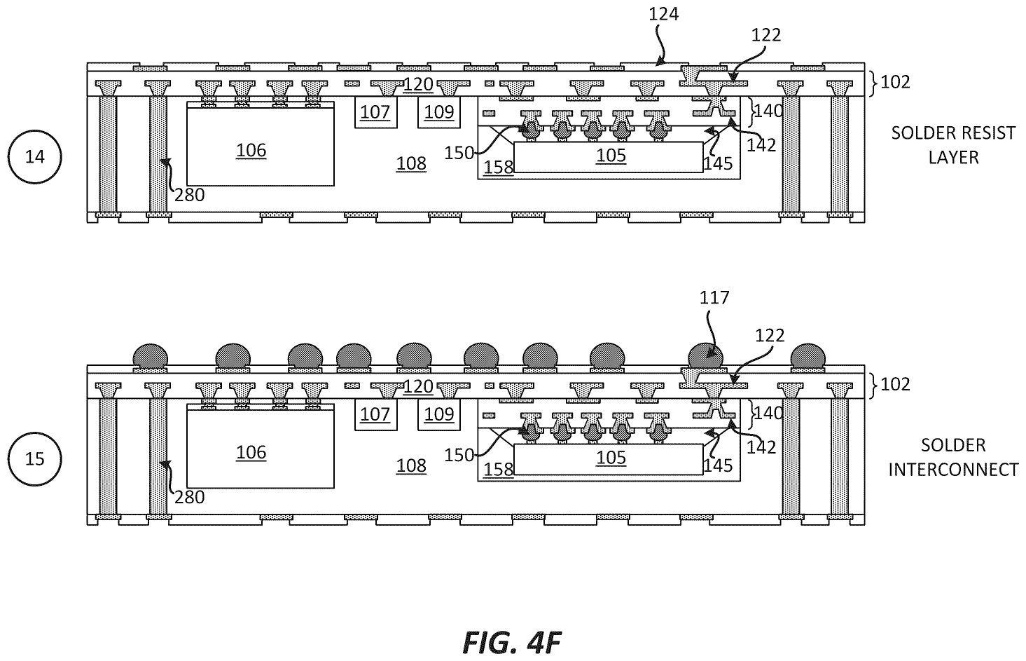

In some implementations, fabricating a package includes several processes. FIGS. 4A-4F illustrate an exemplary sequence for providing or fabricating a package. In some implementations, the sequence of FIGS. 4A-4F may be used to provide or fabricate the package 200. However, the process of FIGS. 4A-4F may be used to fabricate any of the packages (e.g., 100) described in the disclosure.

It should be noted that the sequence of FIGS. 4A-4F may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 4A, illustrates a state after the integrated device 104, the integrated device 106, the passive device 107 and the passive device 109 are placed on a carrier 400. A pick and place process may be used to place the integrated device 104, the integrated device 106, the passive device 107 and the passive device 109 on the carrier 400. The carrier 400 may include tape. The integrated device 104 includes a metallization portion 140, a plurality of solder interconnects 150, an underfill 145, an integrated device 105, and an encapsulation layer 158.

Stage 2 illustrates a state after an encapsulation layer 108 is formed. The encapsulation layer 108 may be formed over the carrier 400, the integrated device 104, the integrated device 106, the passive device 107 and the passive device 109. The encapsulation layer 108 may be coupled to the carrier 400, the integrated device 104, the integrated device 106, the passive device 107 and the passive device 109. The encapsulation layer 108 may encapsulate the integrated device 104, the integrated device 106, the passive device 107 and the passive device 109.

The encapsulation layer 108 may include a mold, a resin and/or an epoxy. The encapsulation layer 108 may be a means for encapsulation. The encapsulation layer 108 may be provided by using a compression and transfer molding process, a sheet molding process, or a liquid molding process. In some implementations, a polishing process and/or a grinding process may be performed on the encapsulation layer 108 to at least provide a flatter surface of the encapsulation layer 108.

Stage 3 illustrates a state after a plurality of cavities 480 are formed in the encapsulation layer 108. The plurality of cavities 480 may be formed using an etching process (e.g., photo etching) and/or a laser process.

Stage 4, as shown in FIG. 4B, illustrates a state after the plurality of through mold vias 280 are formed in the plurality of cavities 480. The plurality of through mold vias 280 may be via interconnects that are formed through a pasting process and/or a plating process.

Stage 5 illustrates a state after a plurality of interconnects 282 are formed over the encapsulation layer 108. A plating process and a patterning process may be used to form the plurality of interconnects 282. The plurality of interconnects 282 may be coupled to the plurality of through mold vias 280.

Stage 6 illustrates a state after a solder resist layer 224 is formed over the encapsulation layer 108 and the plurality of interconnects 282. A deposition, a lamination, an exposure, a development and/or an etching process may be used to form and pattern the solder resist layer 224.

Stage 7, as shown in FIG. 4C, illustrates a state after the carrier 400 is removed, decoupled and/or detached. The carrier 400 may be decoupled from the encapsulation layer 108. Different implementations may decouple the carrier 400 from the encapsulation layer 108 differently. The carrier 400 may be peeled and/or grinded off from the encapsulation layer 108.

Stage 8 illustrates a state after a dielectric layer 410 is formed and coupled to the encapsulation layer 108, the integrated device 106, the passive device 107, the passive device 109 and the metallization portion 140 of the integrated device 104. A deposition and/or a lamination process may be used to form the dielectric layer 410. The dielectric layer 410 may be coupled to the at least one dielectric layer 141.

Stage 9 illustrates a state after a plurality of cavities 412 are formed in the dielectric layer 410. An exposure, a development and/or an etching process may be used to form the plurality of cavities 412.

Stage 10, as shown in FIG. 4D, illustrates a state after a plurality of metallization interconnects 414 are formed in and over the dielectric layer 410. A plating process and a patterning process may be used to form the plurality of metallization interconnects 414. The plurality of metallization interconnects 414 may be coupled to the plurality of through mold vias 280, the integrated device 106, the passive device 107, the passive device 109 and metallization interconnects from the plurality of metallization interconnects 142. For example, the plurality of metallization interconnects 414 may be formed such that the plurality of metallization interconnects 4141 are coupled to (e.g., touching) the plurality of through mold vias 280, at least one interconnect of the integrated device 106, at least one interconnect of the passive device 107, at least one interconnect of the passive device 109 and/or at least one metallization interconnect from the plurality of metallization interconnects 142.

Stage 11 illustrates a state after a dielectric layer 420 is formed and coupled to dielectric layer 410. A deposition and/or a lamination process may be used to form the dielectric layer 420. It is noted that the dielectric layer 410 and the dielectric layer 420 may be represented by the dielectric layer 120.

Stage 12, as shown in FIG. 4E, illustrates a state after a plurality of cavities 422 are formed in the dielectric layer 120. An exposure, a development and/or an etching process may be used to form the plurality of cavities 422.

Stage 13 illustrates a state after a plurality of metallization interconnects 424 are formed in and over the dielectric layer 420. A plating process and a patterning process may be used to form the plurality of metallization interconnects 424. The plurality of metallization interconnects 424 may be coupled to the plurality of metallization interconnects 414. The plurality of metallization interconnects 414 and the plurality of metallization interconnects 424 may be represented by the plurality of metallization interconnects 122. The plurality of metallization interconnects 122 and the at least one dielectric layer 120 may form a metallization portion 102. The metallization portion 102 may be a second metallization portion. The metallization portion 102 may be fabricated using a method that is the same and/or similar to the method as described in FIGS. 7A-7B. Stage 13 illustrates a bottom side of the metallization portion 102 coupled to a bottom side of the metallization portion 140.

Stage 14, as shown in FIG. 4F, illustrates a state after a solder resist layer 124 is formed over portions of the metallization portion 102, the at least one dielectric layer 120 and/or the plurality of metallization interconnects 122. A deposition, a lamination, an exposure, a development and/or an etching process may be used to form and pattern the solder resist layer 124.

Stage 15 illustrates a state after a plurality of solder interconnects 117 are coupled to the metallization portion 102. The plurality of solder interconnects 117 may be coupled to the first side (e.g., top side) of the metallization portion 102. A solder reflow process may be used to couple the plurality of solder interconnects 117 to the plurality of metallization interconnects 122 of the metallization portion 102.

### Exemplary Sequence for Fabricating a Package Comprising a First Metallization Portion and a Second Metallization Portion

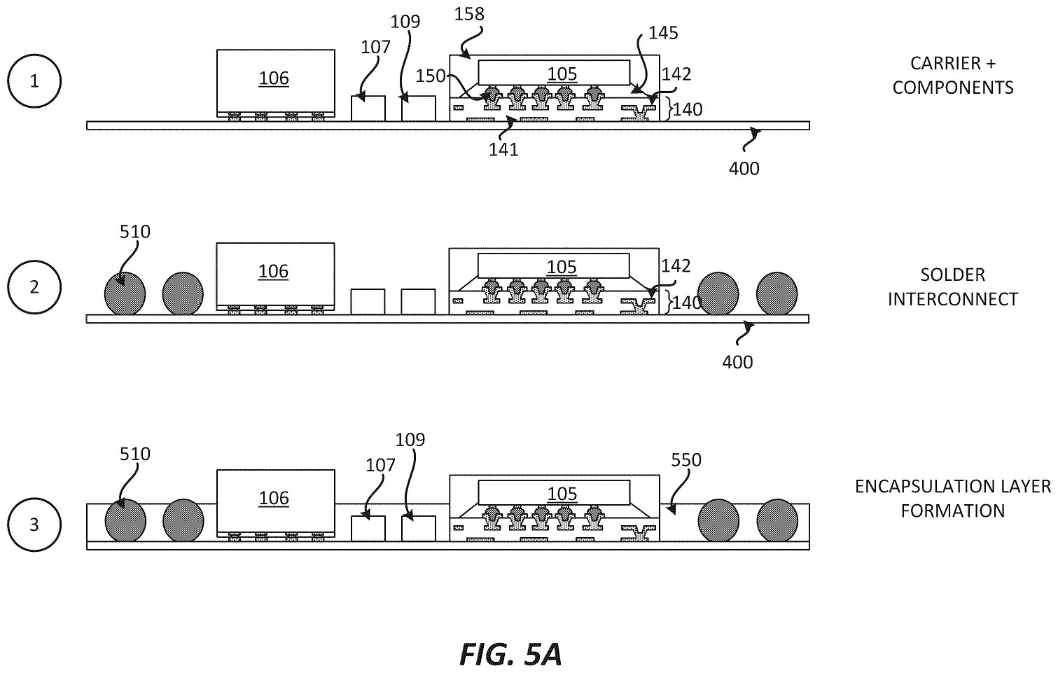

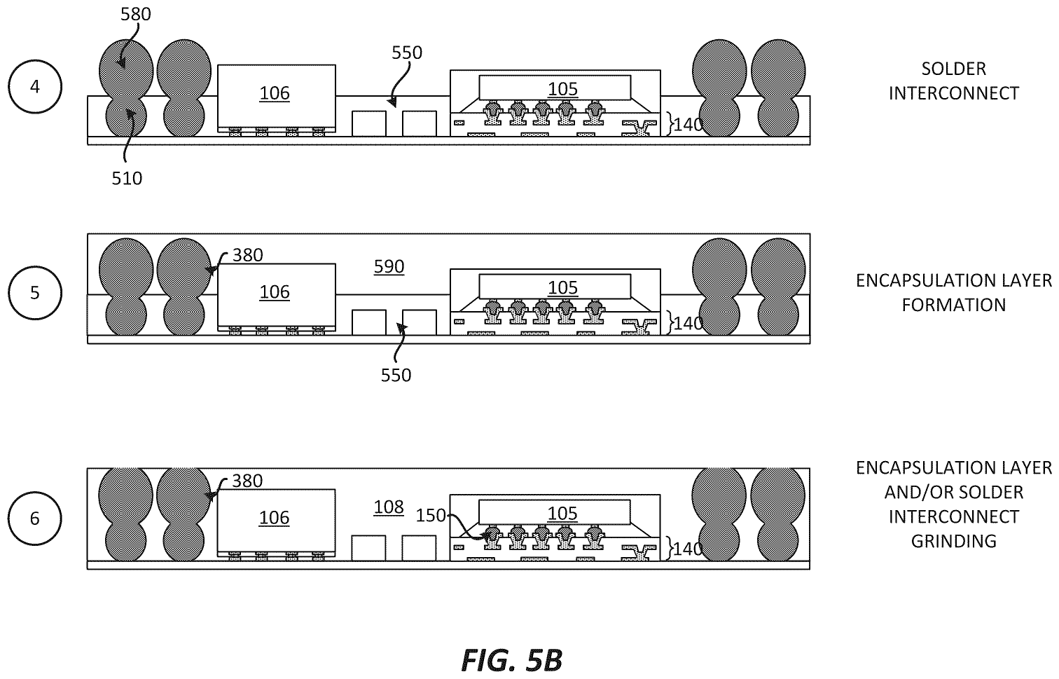

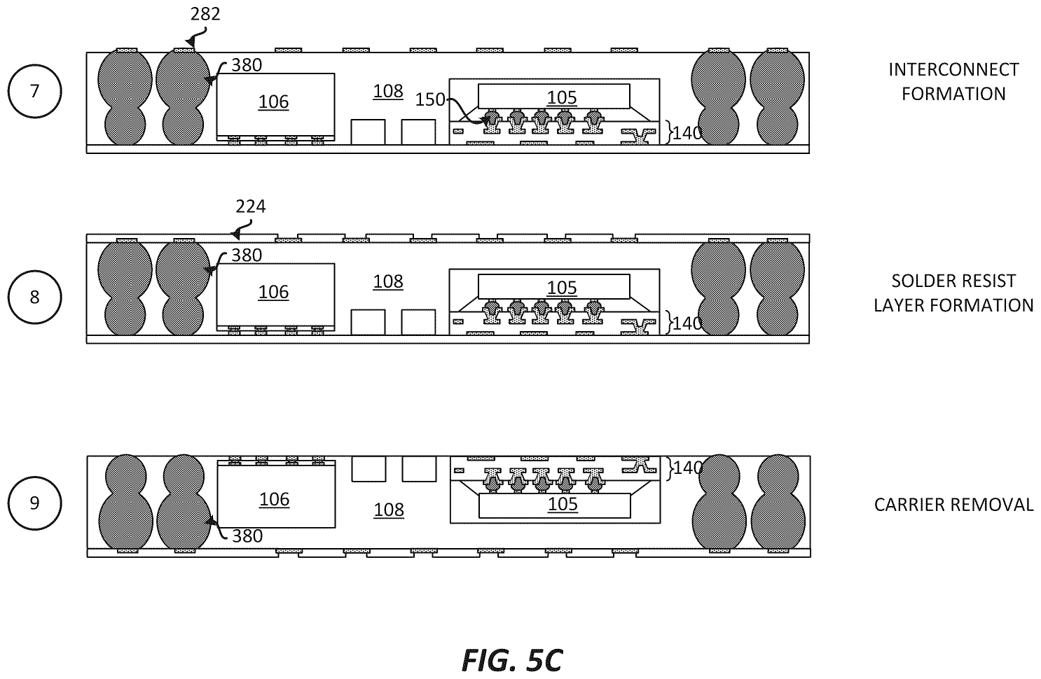

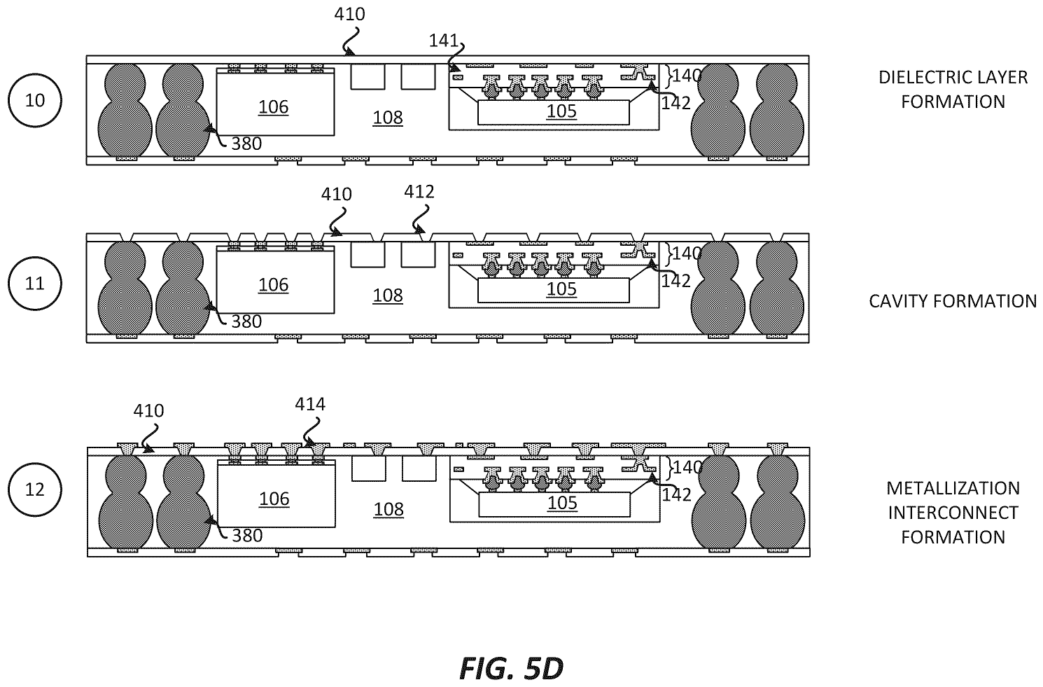

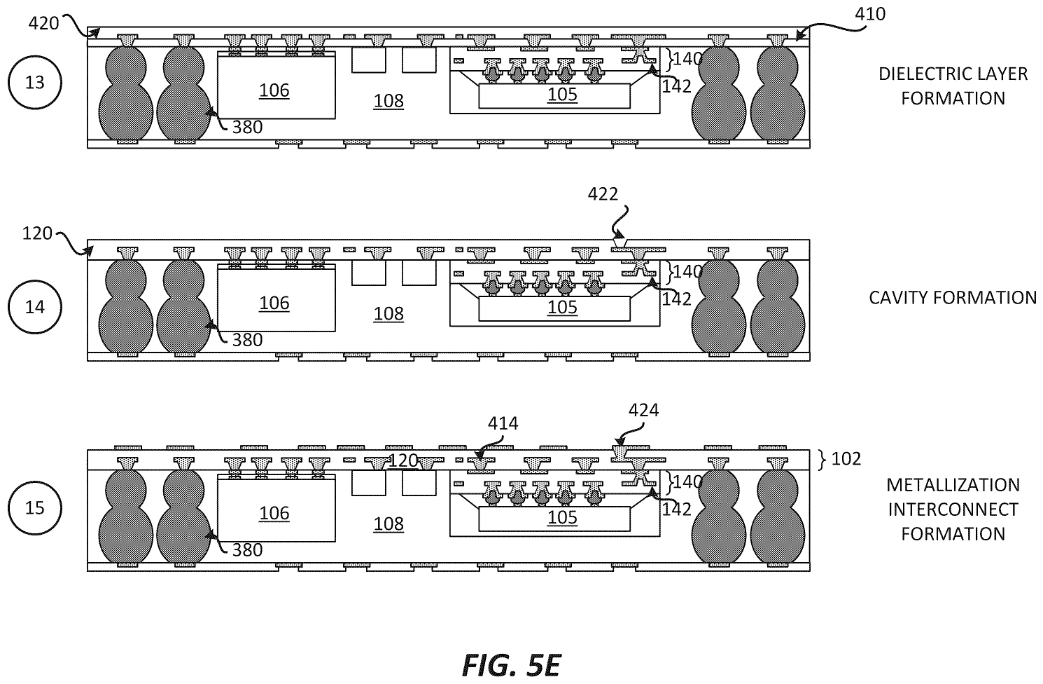

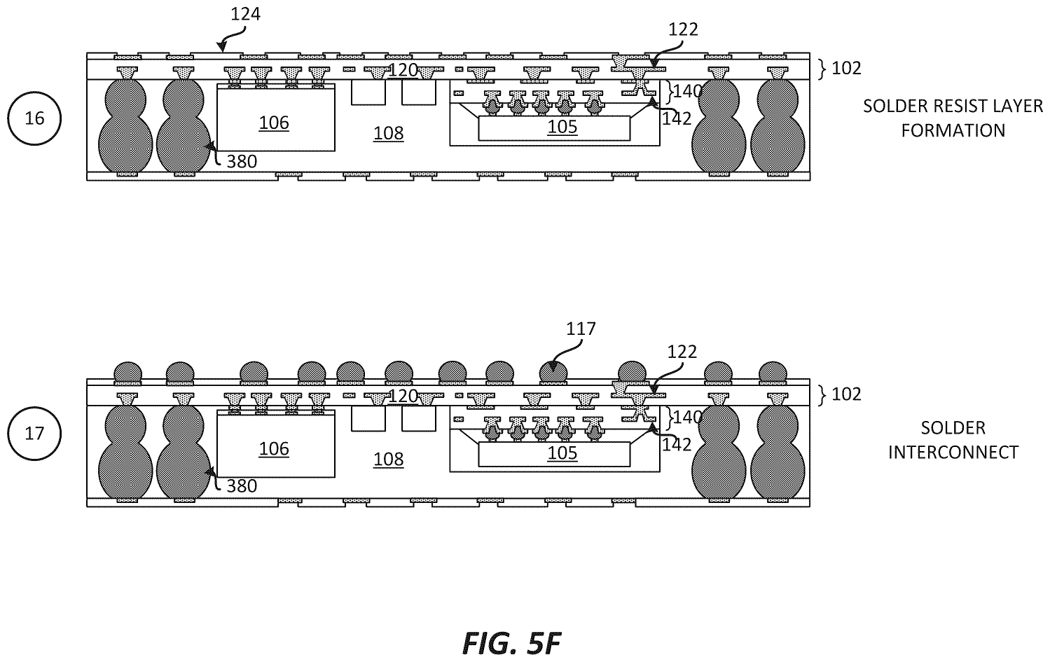

In some implementations, fabricating a package includes several processes. FIGS. 5A-5F illustrate an exemplary sequence for providing or fabricating a package. In some implementations, the sequence of FIGS. 5A-5F may be used to provide or fabricate the package 300. However, the process of FIGS. 5A-5F may be used to fabricate any of the packages (e.g., 100) described in the disclosure.

It should be noted that the sequence of FIGS. 5A-5F may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 5A, illustrates a state after the integrated device 104, the integrated device 106, the passive device 107 and the passive device 109 are placed on a carrier 400. A pick and place process may be used to place the integrated device 104, the integrated device 106, the passive device 107 and the passive device 109 on the carrier 400. The carrier 400 may include tape. The integrated device 104 includes a metallization portion 140, a plurality of solder interconnects 150, an underfill 145, an integrated device 105, and an encapsulation layer 158.

Stage 2 illustrates a state after a plurality of solder interconnects 510 are provided on the carrier 400. A reflow process may be used to provide and/or form the plurality of solder interconnects 510.

Stage 3 illustrates a state after an encapsulation layer 550 is formed. The encapsulation layer 550 may be formed over and/or around the carrier 400, the integrated device 106, the passive device 107, the passive device 109 and the plurality of solder interconnects 510. The encapsulation layer 550 may be coupled to the carrier 400, the integrated device 104, the integrated device 106, the passive device 107, the passive device 109 and the plurality of solder interconnects 510. The encapsulation layer 550 may encapsulate at least part of the integrated device 104, at least part of the integrated device 106, at least part of the passive device 107, at least part of the passive device 109 and/or at least part of the plurality of solder interconnects 510.

The encapsulation layer 550 may include a mold, a resin and/or an epoxy. The encapsulation layer 550 may be a means for encapsulation. The encapsulation layer 550 may be provided by using a compression and transfer molding process, a sheet molding process, or a liquid molding process.

Stage 4, as shown in FIG. 5B, illustrates a state after a plurality of solder interconnects 580 are provided. A reflow process may be used to provide and/or form the plurality of solder interconnects 580. The plurality of solder interconnects 580 may be coupled to the plurality of solder interconnects 510.

Stage 5 illustrates a state after an encapsulation layer 590 is formed. The encapsulation layer 590 may be formed over the encapsulation layer 550, the integrated device 106, the passive device 107, the passive device 109, the plurality of solder interconnects 510 and the plurality of solder interconnects 580. The encapsulation layer 590 may be coupled to the encapsulation layer 550, the integrated device 104, the integrated device 106, the passive device 107, the passive device 109, the plurality of solder interconnects 510 and the plurality of solder interconnects 580. The encapsulation layer 590 may encapsulate at least part of the integrated device 104, at least part of the integrated device 106, at least part of the passive device 107, at least part of the passive device 109, at least part of the plurality of solder interconnects 510 and/or at least part of the plurality of solder interconnects 580. The plurality of solder interconnects 510 and the plurality of solder interconnects 580 may be represented by the plurality of through mold solder interconnects 380. The encapsulation layer 590 may include a mold, a resin and/or an epoxy. The encapsulation layer 590 may be a means for encapsulation. The encapsulation layer 590 may be provided by using a compression and transfer molding process, a sheet molding process, or a liquid molding process. There may or may not be an interface between the encapsulation layer 550 and the encapsulation layer 590. The encapsulation layer 550 and/or the encapsulation layer 590 may represented as the encapsulation layer 108.

Stage 6 illustrates a state after portions of the encapsulation layer 108 and portions of the plurality of through mold solder interconnects 380 are removed. In some implementations, a polishing process and/or a grinding process may be performed on the encapsulation layer 108 and the plurality of through mold solder interconnects 380 to at least flatten the surface of the encapsulation layer 108 and the plurality of through mold solder interconnects 380.

Stage 7, as shown in FIG. 5C, illustrates a state after a plurality of interconnects 282 are formed over the encapsulation layer 108. A plating process and a patterning process may be used to form the plurality of interconnects 282. The plurality of interconnects 282 may be coupled to the plurality of through mold solder interconnects 380.

Stage 8 illustrates a state after a solder resist layer 224 is formed over the encapsulation layer 108 and the plurality of interconnects 282. A deposition, a lamination, an exposure, a development and/or an etching process may be used to form and pattern the solder resist layer 224.

Stage 9 illustrates a state after the carrier 400 is removed, decoupled and/or detached. The carrier 400 may be decoupled from the encapsulation layer 108. Different implementations may decouple the carrier 400 from the encapsulation layer 108 differently. The carrier 400 may be peeled and/or grinded off from the encapsulation layer 108.

Stage 10, as shown in FIG. 5D, illustrates a state after a dielectric layer 410 is formed and coupled to the encapsulation layer 108, the integrated device 106, the passive device 107, the passive device 109 and the metallization portion 140 of the integrated device 104. A deposition and/or a lamination process may be used to form the dielectric layer 410. The dielectric layer 410 may be coupled to the at least one dielectric layer 141.

Stage 11 illustrates a state after a plurality of cavities 412 are formed in the dielectric layer 410. An exposure, a development and/or an etching process may be used to form the plurality of cavities 412.

Stage 12 illustrates a state after a plurality of metallization interconnects 414 are formed in and over the dielectric layer 410. A plating process and a patterning process may be used to form the plurality of metallization interconnects 414. The plurality of metallization interconnects 414 may be coupled to the plurality of through mold solder interconnects 380, the integrated device 106, the passive device 107, the passive device 109 and metallization interconnects from the plurality of metallization interconnects 142. For example, the plurality of metallization interconnects 414 may be formed such that the plurality of metallization interconnects 414 are coupled to (e.g., touching) the plurality of through mold solder interconnects 380, at least one interconnect of the integrated device 106, at least one interconnect of the passive device 107, at least one interconnect of the passive device 109 and/or at least one metallization interconnect from the plurality of metallization interconnects 142.

Stage 13, as shown in FIG. 5E, illustrates a state after a dielectric layer 420 is formed and coupled to the dielectric layer 410. A deposition and/or a lamination process may be used to form the dielectric layer 420. It is noted that the dielectric layer 410 and the dielectric layer 420 may be represented by the dielectric layer 120.

Stage 14 illustrates a state after a plurality of cavities 422 are formed in the dielectric layer 120. An exposure, a development and/or an etching process may be used to form the plurality of cavities 422.

Stage 15 illustrates a state after a plurality of metallization interconnects 424 are formed in and over the dielectric layer 420. A plating process and a patterning process may be used to form the plurality of metallization interconnects 424. The plurality of metallization interconnects 424 may be coupled to the plurality of metallization interconnects 414. The plurality of metallization interconnects 414 and the plurality of metallization interconnects 424 may be represented by the plurality of metallization interconnects 122. The plurality of metallization interconnects 122 and the at least one dielectric layer 120 may form a metallization portion 102. The metallization portion 102 may be a second metallization portion. The metallization portion 102 may be fabricated using a method that is the same and/or similar to the method as described in FIGS. 7A-7B.

Stage 16, as shown in FIG. 5F, illustrates a state after a solder resist layer 124 is formed over portions of the metallization portion 102, the at least one dielectric layer 120 and/or the plurality of metallization interconnects 122. A deposition, a lamination, an exposure, a development and/or an etching process may be used to form and pattern the solder resist layer 124.

Stage 17 illustrates a state after a plurality of solder interconnects 117 are coupled to the metallization portion 102. The plurality of solder interconnects 117 may be coupled to the first side (e.g., top side) of the metallization portion 102. A solder reflow process may be used to couple the plurality of solder interconnects 117 to the plurality of metallization interconnects 122 of the metallization portion 102.

### Exemplary Flow Diagram of a Method for Fabricating a Package Comprising a First Metallization Portion and a Second Metallization Portion

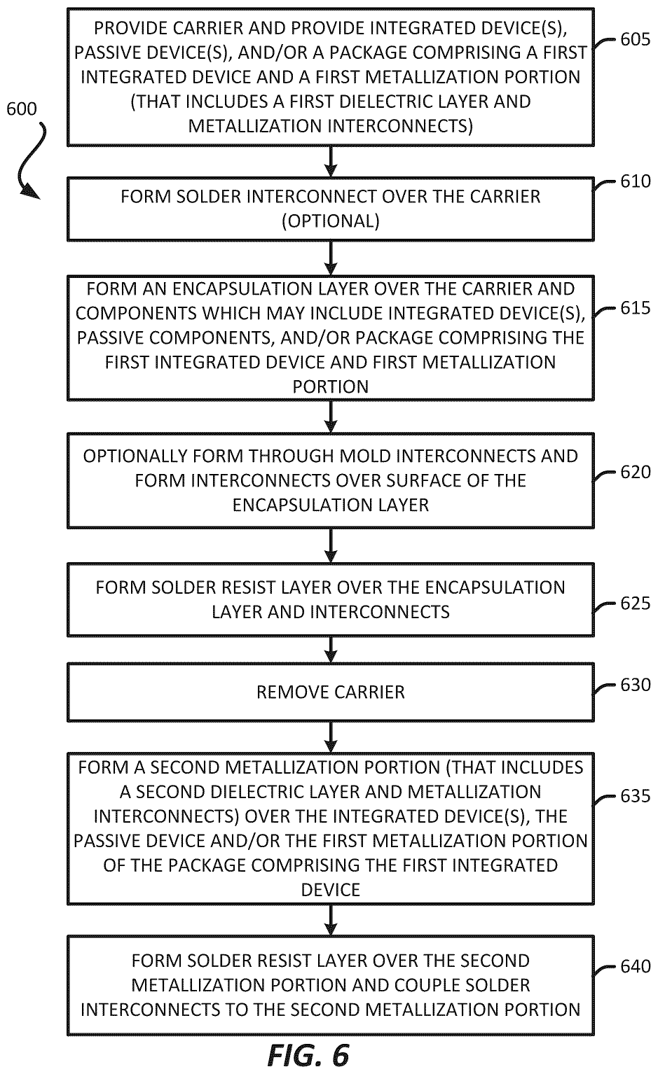

In some implementations, fabricating a package includes several processes. FIG. 6 illustrates an exemplary flow diagram of a method 600 for providing or fabricating a package. In some implementations, the method 600 of FIG. 6 may be used to provide or fabricate at least part of the package 100 of FIG. 2 that is described in the disclosure. However, the method 600 may be used to provide or fabricate any of the packages (e.g., 100, 200, 300) described in the disclosure.

It should be noted that the method 600 of FIG. 6 may combine one or more processes in order to simplify and/or clarify the method for providing or fabricating a package. In some implementations, the order of the processes may be changed or modified.

The method provides (at 605) a carrier (e.g., 400). The method places (at 605) at least one integrated device and/or at least one passive device on the carrier. A pick and place process may be used to place and/or couple the integrated devices and/or the passive devices to the carrier. For example, the method may place and/or couple the integrated device 104, the integrated device 106, the passive device 107 and the passive device 109 to the carrier 400. The integrated device 104 includes a metallization portion 140 (e.g., first metallization portion), a plurality of solder interconnects 150, an underfill 145, an integrated device 105 (e.g., first integrated device), and an encapsulation layer 158. The carrier 400 may include tape. Thus, in one example, the method a first package that includes a first integrated device and a first metallization portion coupled to the first integrated device. The first metallization portion includes at least one first dielectric layer and a first plurality of metallization interconnects. The method may also provide a second integrated device. Stage 1 of FIG. 4A and Stage 1 of FIG. 5A illustrate and describe examples of providing a carrier and placing integrated devices and/or passive devices on the carrier.

The method optionally forms (at 610) a plurality of solder interconnects (e.g., 510) on the carrier. A reflow process may be used to provide and/or form the plurality of solder interconnects. Stage 2 of FIG. 5A illustrates and describes an example of forming a plurality of solder interconnects.

The method forms (at 615) an encapsulation layer (e.g., 108, 550). For example, the encapsulation layer (e.g., 108, 550) may be formed over the carrier 400, the integrated device 106, the passive device 107, the passive device 109 and the plurality of solder interconnects 510 (if present). The encapsulation layer may be coupled to the carrier 400, the integrated device 104, the integrated device 106, the passive device 107, the passive device 109 and the plurality of solder interconnects 510. The encapsulation layer may encapsulate at least part of the integrated device 104, at least part of the integrated device 106, at least part of the passive device 107, at least part of the passive device 109 and/or at least part of the plurality of solder interconnects 510. Thus, in one example, the method forms an encapsulation layer over the first package and the second integrated device. The encapsulation layer may include a mold, a resin and/or an epoxy. The encapsulation layer may be a means for encapsulation. The encapsulation layer may be provided by using a compression and transfer molding process, a sheet molding process, or a liquid molding process. Stage 2 of FIG. 4A and Stage 3 of FIG. 5A illustrate and describe examples of forming an encapsulation layer. In some implementations, the method may go back to optionally form (at 610) a plurality of solder interconnects (e.g., 580). Stage 4 of FIG. 5B illustrates and describes an example of forming a plurality of solder interconnects. In such instances, the method may then form (at 615) another encapsulation layer (e.g., 590). Stage 5 of FIG. 5B illustrate and describe an example of forming an encapsulation layer. The plurality of solder interconnects that are located in the encapsulation layer may be a form of a plurality of through mold interconnects. In some implementations, a polishing process and/or a grinding process may be performed on the encapsulation layer and the plurality of through mold solder interconnects (if present) to at least flatten the surface of the encapsulation layer and the plurality of through mold solder interconnects. Stage 6 of FIG. 5B illustrates and describes an example of removing portions of an encapsulation layer and portions of solder interconnects.

The method optionally forms (at 620) a plurality of through mold interconnects in the encapsulation layer and forms (at 620) interconnects (e.g., 282) over a surface of the encapsulation layer. Forming the plurality of through mold interconnects may include forming a plurality of through mold vias 280. Forming the plurality of through mold interconnects includes forming a plurality of cavities in the encapsulation layer and forming interconnects (e.g., vias) in the plurality of cavities. Stage 3 of FIG. 4A through Stage 5 of FIG. 4B illustrate and describe an example of forming a plurality of through mold interconnects and interconnects. Stage 7 of FIG. 5C illustrates and describes an example of forming interconnects over a surface of an encapsulation layer.

The method forms (at 625) a solder resist layer over the encapsulation layer and the plurality of interconnects. For example, a solder resist layer 224 may be formed over the encapsulation layer 108 and the plurality of interconnects 282. A deposition, a lamination, an exposure, a development and/or an etching process may be used to form and pattern the solder resist layer 224. Stage 6 of FIG. 4B and Stage 8 of FIG. 5C illustrate and describe examples of forming a solder resist layer.

The method removes (at 630) the carrier. For example, the carrier 400 may be removed, decoupled and/or detached from the encapsulation layer 108. Different implementations may decouple the carrier 400 from the encapsulation layer 108 differently. The carrier 400 may be grinded off from the encapsulation layer 108. Stage 7 of FIG. 4B and Stage 9 of FIG. 5C illustrate examples of removing a carrier.

The method forms (at 635) a metallization portion over a surface of the encapsulation layer, at least one integrated device, at least one passive device and another metallization. For example, a metallization portion 102 (e.g., second metallization portion) may be formed over a surface of the encapsulation layer 108, the integrated device 106, the metallization portion 140, the passive device 107 and the passive device 109. Forming the metallization portion includes forming at least one dielectric layer and a plurality of metallization interconnects. Thus, in one example, the method forms a second metallization portion over a second integrated device, a first metallization portion of the first package and the encapsulation layer. The second metallization portion includes at least one second dielectric layer and a second plurality of metallization interconnects. Stage 8 of FIG. 4C through Stage 13 of FIG. 4E illustrate an example of forming a metallization portion. Stage 10 of FIG. 5D through Stage 15 of FIG. 5E illustrate an example of forming a metallization portion.

The method forms (at 640) a solder resist layer over the metallization portion (e.g., second metallization portion) and couple a plurality of solder interconnects to the metallization portion. For example, a solder resist layer 124 may be formed over the metallization portion 102, and a plurality of solder interconnects 117 may be coupled to the metallization portion 102. Stage 14 of FIG. 4F and Stage 16 of FIG. 5F illustrate and describe examples of forming a solder resist layer.

In some implementations, several packages are fabricated at the same time. In such cases, the method may singulate the package (e.g., 100, 200, 300).

### Exemplary Sequence for Fabricating a Metallization Portion

In some implementations, fabricating a metallization portion includes several processes. FIGS. 7A-7B illustrate an exemplary sequence for providing or fabricating a metallization portion. In some implementations, the sequence of FIGS. 7A-7B may be used to provide or fabricate the metallization portion 102. However, the process of FIGS. 7A-7B may be used to fabricate any of the metallization portions (e.g., 140) described in the disclosure.

It should be noted that the sequence of FIGS. 7A-7B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure. The sequence of FIGS. 7A-7B may be used to fabricate a metallization portion over one or more components (fabricate over an integrated device and/or another metallization portion), instead of a carrier.

Stage 1, as shown in FIG. 12A, illustrates a state after a carrier 700 is provided. A seed layer 701 and interconnects 702 may be located over the carrier 700. The interconnects 702 may be located over the seed layer 701. A plating process and etching process may be used to form the interconnects 702. In some implementations, the carrier 700 may be provided with the seed layer 701 and a metal layer that is patterned to form the interconnects 702. The interconnects 702 may represent at least some of the metallization interconnects from the plurality of metallization interconnects 122.

Stage 2 illustrates a state after a dielectric layer 720 is formed over the carrier 700, the seed layer 701 and the interconnects 702. A deposition and/or lamination process may be used to form the dielectric layer 720. The dielectric layer 720 may include prepreg and/or polyimide. The dielectric layer 720 may include a photo-imageable dielectric. However, different implementations may use different materials for the dielectric layer.

Stage 3 illustrates a state after a plurality of cavities 710 is formed in the dielectric layer 720. The plurality of cavities 710 may be formed using an etching process (e.g., photo etching process) or laser process.

Stage 4 illustrates a state after interconnects 712 are formed in and over the dielectric layer 720, including in and over the plurality of cavities 710. For example, a via, pad and/or traces may be formed. A plating process may be used to form the interconnects. Stage 4 illustrates that some portions of the interconnects 712 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 5 illustrates a state after a dielectric layer 722 is formed over the dielectric layer 720 and the interconnects 712. A deposition and/or lamination process may be used to form the dielectric layer 722. The dielectric layer 722 may include prepreg and/or polyimide. The dielectric layer 722 may include a photo-imageable dielectric. However, different implementations may use different materials for the dielectric layer.

Stage 6, as shown in FIG. 7B, illustrates a state after a plurality of cavities 730 is formed in the dielectric layer 722. The plurality of cavities 730 may be formed using an etching process (e.g., photo etching process) or laser process.

Stage 7 illustrates a state after interconnects 714 are formed in and over the dielectric layer 722, including in and over the plurality of cavities 730. For example, a via, pad and/or traces may be formed. A plating process may be used to form the interconnects. Stage 7 illustrates that some portions of the interconnects 714 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 8 illustrates a state after the carrier 700 is decoupled (e.g., detached, removed, grinded out) from at least one dielectric layer 120 and the seed layer 701, portions of the seed layer 701 are removed (e.g., etched out), leaving the metallization portion 102 that includes at least one dielectric layer 120 and the plurality of metallization interconnects 122. The at least one dielectric layer 120 may represent the dielectric layer 720 and/or the dielectric layer 722. The plurality of metallization interconnects 122 may represent the interconnects 702, 712 and/or 714. As mentioned above, the plurality of metallization interconnects 122 may include a plurality of redistribution interconnects. The plurality of metallization interconnects 122 may have a thickness in a range of about 3-7 micrometers. For example, one or more redistribution interconnects from the plurality of metallization interconnects 122 may have a thickness that is in a range of about 3-7 micrometers, which is less than the thickness of interconnects from a package substrate (e.g., 304). Similar or the same dimensions may be applicable to a plurality of metallization interconnects 142 from the metallization portion 140. Stage 8 illustrate what may be considered the top side/top portion of the metallization portion 102 and what may be considered the bottom side/bottom portion of the metallization portion. The metallization portion 140 may have top side/top portion and a bottom side/bottom portion in a similar fashion.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

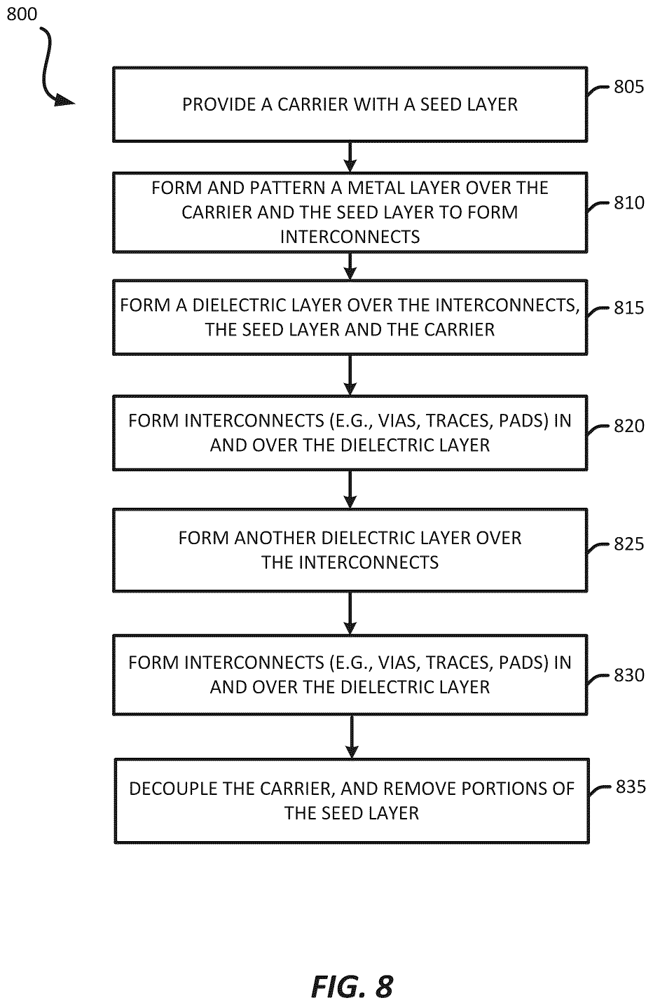

In some implementations, fabricating a metallization portion includes several processes. FIG. 8 illustrates an exemplary flow diagram of a method 800 for providing or fabricating a metallization portion. In some implementations, the method 800 of FIG. 8 may be used to provide or fabricate the metallization portion(s) of the disclosure. For example, the method 800 of FIG. 8 may be used to fabricate the metallization portion 102.

It should be noted that the method 800 of FIG. 8 may combine one or more processes in order to simplify and/or clarify the method for providing or fabricating a metallization portion. In some implementations, the order of the processes may be changed or modified.

The method provides (at 805) a carrier (e.g., 700). Different implementations may use different materials for the carrier 700. The carrier 700 may include a seed layer (e.g., 701). The seed layer 701 may include a metal (e.g., copper). The carrier may include a substrate, glass, quartz and/or carrier tape. Stage 1 of FIG. 7A illustrates and describes an example of a carrier with a seed layer that is provided.

The method forms and patterns (at 810) interconnects over the carrier 700 and the seed layer 701. A metal layer may be patterned to form interconnects. A plating process may be used to form the metal layer and interconnects. In some implementations, the carrier and seed layer may include a metal layer. The metal layer is located over the seed layer and the metal layer may be patterned to form interconnects (e.g., 122). Stage 1 of FIG. 7A illustrates and describes an example of forming and patterning interconnects over a seed layer and a carrier.

The method forms (at 815) a dielectric layer 720 over the interconnects 702, the seed layer 701, and the carrier 700. A deposition and/or lamination process may be used to form the dielectric layer 720. The dielectric layer 720 may include prepreg and/or polyimide. The dielectric layer 720 may include a photo-imageable dielectric. Forming the dielectric layer 720 may also include forming a plurality of cavities (e.g., 710) in the dielectric layer 720. The plurality of cavities may be formed using an etching process (e.g., photo etching) or laser process. Stages 2-3 of FIG. 7A illustrate and describe an example of forming a dielectric layer and cavities in the dielectric layer.

The method forms (at 820) interconnects in and over the dielectric layer. For example, the interconnects 712 may be formed in and over the dielectric layer 720. A plating process may be used to form the interconnects. Forming interconnects may include providing a patterned metal layer over and/or in the dielectric layer. Forming interconnects may also include forming interconnects in cavities of the dielectric layer. Portions of the interconnects that are formed may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). Stage 4 of FIG. 7A illustrates and describes an example of forming interconnects in and over a dielectric layer.

The method forms (at 825) a dielectric layer 722 over the dielectric layer 720 and the interconnects 712. A deposition and/or lamination process may be used to form the dielectric layer 722. The dielectric layer 722 may include prepreg and/or polyimide. The dielectric layer 722 may include a photo-imageable dielectric. Forming the dielectric layer 722 may also include forming a plurality of cavities (e.g., 730) in the dielectric layer 722. The plurality of cavities may be formed using an etching process (e.g., photo etching) or laser process. Stages 5-6 of FIGS. 7A-7B illustrate and describe an example of forming a dielectric layer and cavities in the dielectric layer.

The method forms (at 830) interconnects in and over the dielectric layer. For example, the interconnects 714 may be formed in and over the dielectric layer 722. A plating process may be used to form the interconnects. Forming interconnects may include providing a patterned metal layer over and/or in the dielectric layer. Forming interconnects may also include forming interconnects in cavities of the dielectric layer. Portions of the interconnects that are formed may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). Stage 7 of FIG. 7B illustrates and describes an example of forming interconnects in and over a dielectric layer.

The method decouples (at 835) the carrier (e.g., 700) from the seed layer (e.g., 701). The carrier 700 may be detached and/or grinded off. The method may also remove (at 835) portions of the seed layer (e.g., 701). An etching process may be used to remove portions of the seed layer 701. Stage 8 of FIG. 7B illustrates and describes an example of decoupling a carrier and seed layer removal.

Different implementations may use different processes for forming the metal layer(s). In some implementations, a chemical vapor deposition (CVD) process, a physical vapor deposition (PVD) process, a sputtering process, a spray coating process, and/or a plating process may be used to form the metal layer(s).

### Exemplary Electronic Devices

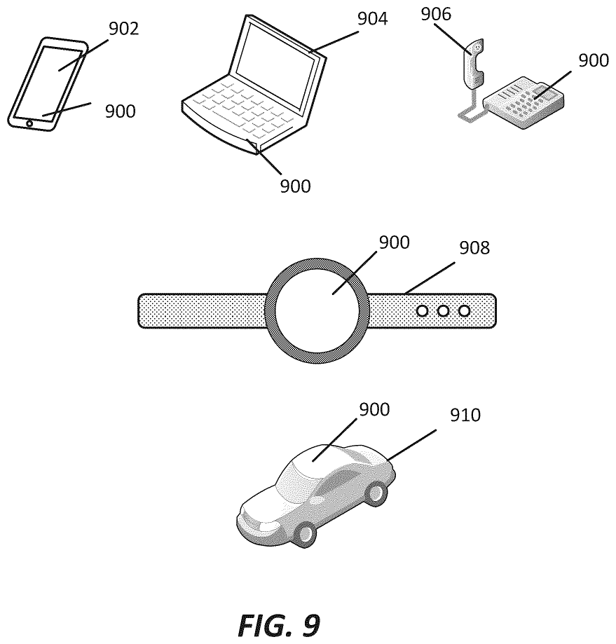

FIG. 9 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 902, a laptop computer device 904, a fixed location terminal device 906, a wearable device 908, or automotive vehicle 910 may include a device 900 as described herein. The device 900 may be, for example, any of the devices and/or integrated circuit (IC) packages described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4F, 5A-5F, 6, 7A-7B, and 8-9 may be rearranged and/or combined into a single component, process, feature or function or embodied in several components, processes, or functions. Additional elements, components, processes, and/or functions may also be added without departing from the disclosure. It should also be noted FIGS. 1-3, 4A-4F, 5A-5F, 6, 7A-7B, and 8-9 and its corresponding description in the present disclosure is not limited to dies and/or ICs. In some implementations, FIGS. 1-3, 4A-4F, 5A-5F, 6, 7A-7B, and 8-9 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising: a first integrated device; a first metallization portion coupled to the first integrated device, wherein the first metallization portion comprises: at least one first dielectric layer; and a first plurality of metallization interconnects; a second integrated device; a second metallization portion coupled to the second integrated device and the first metallization portion, wherein the second metallization portion comprises: at least one second dielectric layer; and a second plurality of metallization interconnects; and an encapsulation layer coupled to the first metallization portion, the second integrated device and the second metallization portion.

Aspect 2: The package of aspect 1, wherein the first metallization portion includes a first redistribution portion, wherein the first plurality of metallization interconnects includes a first plurality of redistribution interconnects, wherein the second metallization portion includes a second redistribution portion, and wherein the second plurality of metallization interconnects includes a second plurality of redistribution interconnects.

Aspect 3: The package of aspect 2, wherein a first portion of a first redistribution interconnect from the first plurality of redistribution interconnects, includes a side profile that has a U-shape or a V shape, and wherein a second portion of a second redistribution interconnect from the second plurality of redistribution interconnects, includes a side profile that has a U-shape or a V shape.

Aspect 4: The package of aspect 3, wherein a bottom portion of the first redistribution portion is directly coupled to a bottom portion of the second redistribution portion.

Aspect 5: The package of aspects 1 through 4, further comprising a first encapsulation layer that is coupled to the first integrated device, wherein the encapsulation layer is a second encapsulation layer that is coupled to the first encapsulation layer, and wherein the first integrated device is coupled to the first metallization portion through a plurality of solder interconnects.

Aspect 6: The package of aspects 1 through 5, further comprising a plurality of through mold vias that are coupled to the second metallization portion, wherein the plurality of through mold vias are located in the encapsulation layer.

Aspect 7: The package of aspects 1 through 6, further comprising a plurality of through mold solder interconnects that are coupled to the second metallization portion, wherein the plurality of through mold solder interconnects are located in the encapsulation layer.

Aspect 8: The package of aspects 1 through 7, further comprising: a plurality of through mold interconnects that extend through a thickness of the encapsulation layer, wherein the plurality of through mold interconnects are coupled to the second metallization portion; a plurality of interconnects coupled to a surface of the encapsulation layer; and a third integrated device coupled to the plurality of interconnects through a plurality of solder interconnects.

Aspect 9: The package of aspect 8, wherein the third integrated device is configured to be electrically coupled to the first integrated device through an electrical path that includes at least one solder interconnect from the plurality of solder interconnects, at least one interconnect from the plurality of interconnects, at least one interconnect from the plurality of through mold interconnects, at least one metallization interconnect from the second plurality of metallization interconnects and at least one metallization interconnect from the first plurality of metallization interconnects.

Aspect 10: The package of aspect 9, wherein the third integrated device is configured to be electrically coupled to the second integrated device through another electrical path that includes at least one other solder interconnect from the plurality of solder interconnects, at least one other interconnect from the plurality of interconnects, at least one other interconnect from the plurality of through mold interconnects, and at least one other metallization interconnect from the second plurality of metallization interconnects.

Aspect 11: The package of aspects 8 through 10, wherein the plurality of through mold interconnects includes a plurality of through mold vias and/or a plurality of through mold solder interconnects.

Aspect 12: A device comprising: a first package comprising: a first integrated device; and a first metallization portion coupled to the first integrated device, wherein the first metallization portion comprises: at least one first dielectric layer; and a first plurality of metallization interconnects; a second integrated device; a second metallization portion coupled to the second integrated device and the first metallization portion of the first package, wherein the second metallization portion comprises: at least one second dielectric layer; and a second plurality of metallization interconnects; and an encapsulation layer coupled to the first package, the second integrated device and the second metallization portion.

Aspect 13: The device of aspect 12, wherein the first metallization portion includes a first redistribution portion, wherein the first plurality of metallization interconnects includes a first plurality of redistribution interconnects, wherein the second metallization portion includes a second redistribution portion, and wherein the second plurality of metallization interconnects includes a second plurality of redistribution interconnects.

Aspect 14: The device of aspects 12 through 13, wherein the first integrated device is coupled to the first metallization portion through a plurality of solder interconnects, wherein the first package comprises a first encapsulation layer, and wherein the encapsulation layer is a second encapsulation layer that is coupled to the first encapsulation layer.

Aspect 15: The device of aspects 12 through 14, further comprising a plurality of through mold vias that are coupled to the second metallization portion, wherein the plurality of through mold vias are located in the encapsulation layer.

Aspect 16: The device of aspects 12 through 14, further comprising a plurality of through mold solder interconnects that are coupled to the second metallization portion, wherein the plurality of through mold solder interconnects are located in the encapsulation layer.

Aspect 17: The device of aspect 16, wherein the plurality of through mold solder interconnects include a first plurality of through mold solder interconnects and a second plurality of through mold solder interconnects, and wherein the first plurality of through mold solder interconnects are coupled to the second plurality of through mold solder interconnects.

Aspect 18: The device of aspect 17, wherein the first plurality of through mold solder interconnects include a first width, and wherein the second plurality of through mold solder interconnects include a second width.

Aspect 19: The device of aspect 17, wherein the second plurality of through mold solder interconnects are coupled to the second metallization portion.

Aspect 20: The device of aspects 16 through 19, further comprising: a plurality of interconnects coupled to a surface of the encapsulation layer, wherein the plurality of interconnects are coupled to the plurality of through mold solder interconnects, and a solder resist layer formed over the surface of the encapsulation layer and over at least some of the interconnects from the plurality of interconnects.

Aspect 22: A method for fabricating a package, comprising: providing a first package comprising: a first integrated device; and a first metallization portion coupled to the first integrated device, wherein the first metallization portion comprises: at least one first dielectric layer; and a first plurality of metallization interconnects; providing a second integrated device; forming an encapsulation layer over the first package and the second integrated device; and forming a second metallization portion over the second integrated device, the first metallization portion of the first package and the encapsulation layer, wherein the second metallization portion comprises: at least one second dielectric layer; and a second plurality of metallization interconnects.

Aspect 23: The method of aspect 22, wherein the first integrated device is coupled to the first metallization portion through a plurality of solder interconnects, wherein the first package comprises a first encapsulation layer, and wherein the encapsulation layer is a second encapsulation layer that is coupled to the first encapsulation layer.

Aspect 24: The method of aspects 22 through 23, further comprising forming a plurality of through mold vias in the encapsulation layer, wherein the second metallization portion is coupled to the plurality of mold vias.

Aspect 25: The method of aspects 22 through 23, further comprising forming a plurality of through mold solder interconnects, wherein the second metallization portion is coupled to the plurality of through mold solder interconnects, wherein the encapsulation layer is formed such that the encapsulation layer encapsulates the plurality of through mold solder interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
a first metallization portion coupled to the first integrated device, wherein the first metallization portion comprises:
at least one first dielectric layer; and
a first plurality of metallization interconnects;
a second integrated device;
a second metallization portion coupled to the second integrated device and the first metallization portion, wherein the second metallization portion comprises:
at least one second dielectric layer; and
a second plurality of metallization interconnects; and
an encapsulation layer coupled to the first metallization portion, the second integrated device and the second metallization portion.

2. The package of claim 1,
wherein the first metallization portion includes a first redistribution portion,
wherein the first plurality of metallization interconnects includes a first plurality of redistribution interconnects,
wherein the second metallization portion includes a second redistribution portion, and
wherein the second plurality of metallization interconnects includes a second plurality of redistribution interconnects.

3. The package of claim 2,
wherein a first portion of a first redistribution interconnect from the first plurality of redistribution interconnects, includes a side profile that has a U-shape or a V shape, and
wherein a second portion of a second redistribution interconnect from the second plurality of redistribution interconnects, includes a side profile that has a U-shape or a V shape.

4. The package of claim 3, wherein a bottom portion of the first redistribution portion is directly coupled to a bottom portion of the second redistribution portion.

5. The package of claim 1, further comprising a first encapsulation layer that is coupled to the first integrated device,
wherein the encapsulation layer is a second encapsulation layer that is coupled to the first encapsulation layer, and
wherein the first integrated device is coupled to the first metallization portion through a plurality of solder interconnects.

6. The package of claim 1, further comprising a plurality of through mold vias that are coupled to the second metallization portion, wherein the plurality of through mold vias are located in the encapsulation layer.

7. The package of claim 1, further comprising a plurality of through mold solder interconnects that are coupled to the second metallization portion, wherein the plurality of through mold solder interconnects are located in the encapsulation layer.

8. The package of claim 1, further comprising:
a plurality of through mold interconnects that extend through a thickness of the encapsulation layer, wherein the plurality of through mold interconnects are coupled to the second metallization portion;
a plurality of interconnects coupled to a surface of the encapsulation layer; and
a third integrated device coupled to the plurality of interconnects through a plurality of solder interconnects.

9. The package of claim 8, wherein the third integrated device is configured to be electrically coupled to the first integrated device through an electrical path that includes at least one solder interconnect from the plurality of solder interconnects, at least one interconnect from the plurality of interconnects, at least one interconnect from the plurality of through mold interconnects, at least one metallization interconnect from the second plurality of metallization interconnects and at least one metallization interconnect from the first plurality of metallization interconnects.

10. The package of claim 9, wherein the third integrated device is configured to be electrically coupled to the second integrated device through another electrical path that includes at least one other solder interconnect from the plurality of solder interconnects, at least one other interconnect from the plurality of interconnects, at least one other interconnect from the plurality of through mold interconnects, and at least one other metallization interconnect from the second plurality of metallization interconnects.

11. The package of claim 8, wherein the plurality of through mold interconnects includes a plurality of through mold vias and/or a plurality of through mold solder interconnects.

12. A device comprising:
a first package comprising:
a first integrated device; and
a first metallization portion coupled to the first integrated device, wherein
the first metallization portion comprises:
at least one first dielectric layer; and
a first plurality of metallization interconnects;
a second integrated device;
a second metallization portion coupled to the second integrated device and the first metallization portion of the first package, wherein the second metallization portion comprises:
at least one second dielectric layer; and
a second plurality of metallization interconnects; and
an encapsulation layer coupled to the first package, the second integrated device and the second metallization portion.

13. The device of claim 12,
wherein the first metallization portion includes a first redistribution portion,
wherein the first plurality of metallization interconnects includes a first plurality of redistribution interconnects,
wherein the second metallization portion includes a second redistribution portion, and
wherein the second plurality of metallization interconnects includes a second plurality of redistribution interconnects.

14. The device of claim 12,
wherein the first integrated device is coupled to the first metallization portion through a plurality of solder interconnects,
wherein the first package comprises a first encapsulation layer, and
wherein the encapsulation layer is a second encapsulation layer that is coupled to the first encapsulation layer.

15. The device of claim 12, further comprising a plurality of through mold vias that are coupled to the second metallization portion, wherein the plurality of through mold vias are located in the encapsulation layer.

16. The device of claim 12, further comprising a plurality of through mold solder interconnects that are coupled to the second metallization portion, wherein the plurality of through mold solder interconnects are located in the encapsulation layer.

17. The device of claim 16,
wherein the plurality of through mold solder interconnects include a first plurality of through mold solder interconnects and a second plurality of through mold solder interconnects, and
wherein the first plurality of through mold solder interconnects are coupled to the second plurality of through mold solder interconnects.

18. The device of claim 17,
wherein the first plurality of through mold solder interconnects include a first width, and
wherein the second plurality of through mold solder interconnects include a second width.

19. The device of claim 17, wherein the second plurality of through mold solder interconnects are coupled to the second metallization portion.

20. The device of claim 16, further comprising:
a plurality of interconnects coupled to a surface of the encapsulation layer, wherein the plurality of interconnects are coupled to the plurality of through mold solder interconnects; and
a solder resist layer formed over the surface of the encapsulation layer and over at least some of the interconnects from the plurality of interconnects.

21. The device of claim 12, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

22. A method for fabricating a package, comprising:
providing a first package comprising:
a first integrated device; and
a first metallization portion coupled to the first integrated device, wherein the first metallization portion comprises:
at least one first dielectric layer; and
a first plurality of metallization interconnects;
providing a second integrated device;
forming an encapsulation layer over the first package and the second integrated device; and
forming a second metallization portion over the second integrated device, the first metallization portion of the first package and the encapsulation layer, wherein the second metallization portion comprises:
at least one second dielectric layer; and
a second plurality of metallization interconnects.

23. The method of claim 22,
wherein the first integrated device is coupled to the first metallization portion through a plurality of solder interconnects,
wherein the first package comprises a first encapsulation layer, and
wherein the encapsulation layer is a second encapsulation layer that is coupled to the first encapsulation layer.

24. The method of claim 22, further comprising forming a plurality of through mold vias in the encapsulation layer, wherein the second metallization portion is coupled to the plurality of mold vias.

25. The method of claim 22, further comprising forming a plurality of through mold solder interconnects, wherein the second metallization portion is coupled to the plurality of through mold solder interconnects, wherein the encapsulation layer is formed such that the encapsulation layer encapsulates the plurality of through mold solder interconnects.
